(19) United States
(12) Patent Application Publication
(10) Pub. No.: US 2026/0282908 A1
(43) Pub. Date: Sep. 17, 2026

(54) FLEXIBLE DIAMOND HEAT SPREADER

(71) Applicant: Meta Platforms Technologies, LLC, Menlo Park, CA (US)

(72) Inventor: Nazila Dadvand, Redmond, WA (US)

(21) Appl. No.: 19/548,634

(22) Filed: Feb. 24, 2026

Related U.S. Application Data
(60) Provisional application No. 63/772,282, filed on Mar. 14, 2025.

(51) Int. Cl. H10W 40/25; H10W 70/67

(52) U.S. Cl. CPC H10W 40/254; H10W 40/251; H10W 40/255; H10W 70/688

(57) ABSTRACT

A device of the subject technology includes at least one semiconductor package formed on a substrate, and a diamond heat spreader arranged over the at least one semiconductor package. The substrate and the diamond heat spreader are flexible.

### CROSS REFERENCE TO RELATED APPLICATIONS

The present disclosure is related and claims priority under 35 USC §119(e) to US Provisional Application No. 63/772,282, entitled “FLEXIBLE DIAMOND HEAT SPREADER,” filed on Mar. 14, 2025, the contents of which are herein incorporated by reference, in their entirety, for all purposes.

### TECHNICAL FIELD

The present disclosure generally relates to heat spreaders, and more particularly, to flexible diamond heat spreaders.

### BACKGROUND

Electronic devices continue to become more compact and more powerful, resulting in increased thermal loads within increasingly confined internal spaces. As semiconductor components such as processors, power management ICs, memory modules, and radio-frequency chips operate, they generate heat that must be effectively managed to maintain device performance and reliability. Excessive heat buildup can degrade component efficiency, shorten operational lifespan, or in some cases cause immediate device malfunction. To address these challenges, many electronic assemblies incorporate thermal management structures designed to distribute, conduct, or dissipate heat away from sensitive components. Among these structures, heat spreaders are widely used because they can transfer heat laterally across a larger surface area, reducing localized hot spots and enabling more uniform temperature profiles within the device.

Heat spreaders are commonly fabricated from materials with high in-plane thermal conductivity, such as pyrolytic graphite, copper, aluminum, or composite laminates. Pyrolytic graphite, in particular, is frequently selected due to its combination of low weight, mechanical flexibility, and exceptionally high thermal conductivity, which allows it to efficiently transfer heat from a heat-generating component to a remote region of the device enclosure or to another thermal interface. As device architecture evolves, heat spreaders are increasingly required to conform to complex geometries, integrate with multilayer assemblies, or interface with multiple components simultaneously. These demands highlight the need for improved heat spreader designs that can maintain thermal performance while accommodating the structural and spatial constraints of modern electronic devices.

### SUMMARY

According to some aspects, a device of the subject technology includes at least one semiconductor package formed on a substrate, and a diamond heat spreader arranged over the at least one semiconductor package. The substrate and the diamond heat spreader are flexible.

According to other aspects, a method of the subject technology includes forming a layer of diamond over a flexible substrate, treating a first surface of the layer of diamond using an oxygen plasma. The method further comprises forming a first encapsulating layer on the treated first surface of the layer of diamond.

According to yet other aspects, a wearable device of the subject technology includes at least one semiconductor package including electronic circuitry formed on a substrate, and a diamond heat spreader arranged over the at least one semiconductor package. The substrate and the diamond heat spreader are flexible.

### BRIEF DESCRIPTION OF THE DRAWINGS

To easily identify the discussion of any particular element or act, the most significant digit or digits in a reference number refer to the figure number in which that element is first introduced.

FIG. 1 is a schematic diagram illustrating a cross-sectional view of a portion of an example of a heat spreader, according to some embodiments of the subject disclosure.

FIG. 2 is a flow diagram illustrating an example of a process of fabricating a heat spreader, according to some embodiments of the subject disclosure.

FIG. 3 is a schematic diagram illustrating a cross-sectional view of a device comprising a heat spreader, according to some embodiments of the subject disclosure.

FIG. 4 is a schematic diagram illustrating an example augmented reality (AR) system, according to some embodiments of the subject disclosure.

FIG. 5 is a schematic diagram illustrating an example AR system with a handheld device, according to some embodiments of the subject disclosure.

FIGS. 6A and 6B are schematic diagrams illustrating examples of user interactions within an AR system, according to some embodiments of the subject disclosure.

FIGS. 7A and 7B are schematic diagrams illustrating examples of user interactions within an AR system, according to some embodiments of the subject disclosure.

FIG. 8 is an illustration of an example wrist-wearable device of an AR system, according to some embodiments of the subject disclosure.

FIG. 9 is a block diagram illustrating an example of a wearable AR system, according to some embodiments of the subject disclosure.

FIG. 10 is a schematic diagram illustrating an example of an AR system, according to some embodiments of the subject disclosure.

FIGS. 11A and 11B are schematic diagrams illustrating examples of virtual reality (VR) systems, according to some embodiments of the subject disclosure.

FIG. 12 is a block diagram illustrating an example of system components of artificial and VR systems.

In one or more implementations, not all of the depicted components in each figure may be required, and one or more implementations may include additional components not shown in a figure. Variations in the arrangement and type of the components may be made without departing from the scope of the subject disclosure. Additional components, different components, or fewer components may be utilized within the scope of the subject disclosure.

### DETAILED DESCRIPTION OF EXEMPLARY EMBODIMENTS

The detailed description set forth below describes various configurations of the subject technology and is not intended to represent the only configurations in which the subject technology may be practiced. The detailed description includes specific details for the purpose of providing a thorough understanding of the subject technology. Accordingly, dimensions may be provided in regard to certain aspects as non-limiting examples. However, it will be apparent to those skilled in the art that the subject technology may be practiced without these specific details. In some instances, well-known structures and components are shown in block diagram form in order to avoid obscuring the concepts of the subject technology.

It is to be understood that the present disclosure includes examples of the subject technology and does not limit the scope of the included clauses. Various aspects of the subject technology will now be disclosed according to particular but non-limiting examples. Various embodiments described in the present disclosure may be carried out in different ways and variations, and in accordance with a desired application or implementation.

In the following detailed description, numerous specific details are set forth to provide a full understanding of the present disclosure. It will be apparent, however, to one ordinarily skilled in the art, that embodiments of the present disclosure may be practiced without some of the specific details. In other instances, well-known structures and techniques have not been shown in detail so as not to obscure the disclosure.

The present disclosure is generally directed to an improved heat spreader comprising diamond. As will be explained in greater detail below, embodiments of the present disclosure may provide for a flexible diamond heat spreader that may be utilized in electronic devices. Because diamond has a high thermal conductivity, the improved heat spreader may be very effective at transferring heat. In some cases, an electronic device may comprise an antenna. While some heat spreaders may be electrically conductive and therefore interfere with an antenna, the improved heat spreader comprising diamond described herein may be electrically insulating and therefore may be more readily used in devices that include an antenna.

Electronics device very frequently include a heat spreader to aid in distributing and/or dissipating heat from hot components in the device. For instance, a processor or other semiconductor package generates heat that may damage the processor or other components of a device unless some of that heat is transferred away from the processor. Existing heat spreaders may be made from a material such as pyrolytic graphite that has a high thermal conductivity to effectively transfer heat.

According to some embodiments, an electronic device may comprise a flexible layer of diamond, which can effectively transfer heat within the device. In some embodiments, flexibility of the layer of diamond may be provided, at least in part, by adhering encapsulant layers to one or both sides of the layer of diamond. The successful adhesion of flexible encapsulant layers to a thin layer of diamond provides sufficient support to allow the combination of diamond and encapsulant to be flexed at high angles without any, or with minimal, effect to the ability of the diamond layer to conduct heat. For instance, adhering a roughly 50 µm layer of a polymer to both sides of a 10 µm layer of diamond has been found to produce a heat spreader than can be flexed into a loop an inch or two across. Adhesion of the encapsulant layer(s) to the diamond layer may be achieved through a surface treatment process, which is described below.

A heat spreader that includes a flexible layer of diamond may be employed in a wide variety of electronic devices, including flexible devices such as wearable devices including augmented reality (AR) headsets, smart watches, haptic wristbands, etc.

Some electronic devices include an antenna for wireless communication, and also include an electrically conductive heat spreader, such as a graphite heat spreader. This type of heat spreader has limited placement, as placing it too close to the antenna would reduce the effectiveness of the antenna’s transmission and/or reception. As such, some devices cut openings in a heat spreader to avoid antennas, but this reduces the effectiveness of the heat spreader. The heat spreaders described herein that include a layer of diamond may be electrically insulating and therefore can be placed close to an antenna without meaningfully affecting the antenna’s operation.

Features from any of the embodiments described herein may be used in combination with one another in accordance with the general principles described herein. These and other embodiments, features, and advantages will be more fully understood upon reading the following detailed description in conjunction with the accompanying drawings and claims.

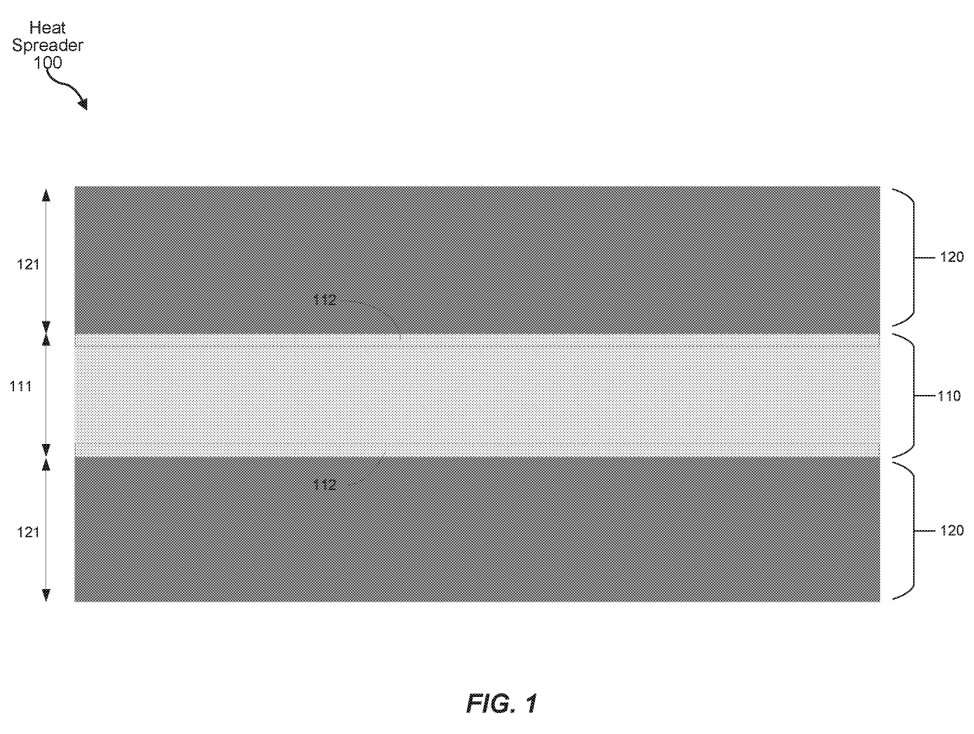

FIG. 1 is a schematic diagram illustrating a cross-sectional view of a portion of an example of a heat spreader, according to some embodiments of the subject disclosure. In the example of FIG. 1, heat spreader 100 comprises a layer of diamond 110 (e.g., laminar layer) chemically adhered to encapsulation layers 120 on opposing faces of the diamond layer. In the example of FIG. 1, the encapsulation layers 120 may each be formed from, or comprise, a polymer such as a thermoplastic polymer. Suitable polymers may include polypropylene, polyimide, and/or polyethylene terephthalate (PET).

As will be described further below, the encapsulation layers 120 may be adhered to the diamond layer 110 subsequent to the surfaces of the diamond layer being treated in a manner that chemically alters the surface of the diamond. Without wishing to be bound by theory, it is believed that the treatment decomposes the diamond lattice at the surface and through oxidation produces phenolic OH groups and/or keto groups, which can form strong covalent bonds with functional groups in the encapsulation layer material. The treated surface layer is identified in FIG. 1 as region 112 (it is appreciated that this is for purposes of illustration and is not necessarily drawn to scale).

In some embodiments, the thickness 111 of the layer of diamond 110 is greater than or equal to 10 µm, 20 µm, 30 µm, 40 µm, 50 µm, or 60 µm. In some embodiments, the thickness 111 of the layer of diamond 110 is less than or equal to 70 µm, 60 µm, 50 µm, 40 µm, 30 µm or 20 µm. Any suitable combinations of the above-referenced ranges are also possible (e.g., the thickness 111 of the layer of diamond 110 is greater than or equal to 20 µm and less than or equal to 40 µm, etc.).

In some embodiments, the thickness 121 of each encapsulation layer 120 is greater than or equal to 20 µm, 30 µm, 40 µm, 50 µm, 60 µm, 70 µm or 80 µm. In some embodiments, the thickness 121 of each encapsulation layer 120 is less than or equal to 90 µm, 80 µm, 70 µm, 60 µm, 50 µm, 40 µm, or 30 µm. Any suitable combinations of the above-referenced ranges are also possible (e.g., the thickness 121 of each encapsulation layer 120 is greater than or equal to 40 µm and less than or equal to 60 µm, etc.). The encapsulation layers 120 may have the same thickness, or different thicknesses.

It may be desirable that the diamond layer 110 and the encapsulating layers 120 have similar coefficients of thermal expansion (CTEs) so that, during use of heat spreader 100 when it is heated, there is not a significant CTE mismatch between the layers. For instance, the ratio of the CTE of the encapsulating layers 120 to the CTE of the diamond layer may be greater than or equal to 0.75, 1, 1.25, 1.5, or 1.75; and/or may be less than or equal to 2, 1.75, 1.5, 1.25 or 1 (e.g., if the CTE of the diamond layer is 1GPa, the CTE of the encapsulating layers may be greater than or equal to 0.75GPa, 1GPa, 1.25GPa, 1.5GPa, or 1.75GPa; and/or may be less than or equal to 2GPa, 1.75GPa, 1.5GPa, 1.25GPa or 1GPa).

It is recognized that both the thermal conductivity and the potential flexibility of the diamond layer 110 in heat spreader 100 are both affected by the grain size of the diamond layer. In particular, as the grain size increases, the thermal conductivity of the diamond layer 110 is expected to increase, but at the same time the flexibility is expected to decrease. In some embodiments, the grain size of diamond layer 110 (e.g., the mean grain size) is greater than or equal to 1 µm, 1.5 µm, 2 µm, 2.5 µm, 3 µm, 3.5 µm, 4 µm, or 4.5 µm. In some embodiments, the grain size of diamond layer 110 is less than or equal to 5 µm, 4.5 µm, 4 µm, 3.5 µm, 3 µm, 2.5 µm, 2 µm, or 1.5 µm. Any suitable combinations of the above-referenced ranges are also possible (e.g., the grain size of diamond layer 110 is greater than or equal to 2.5 µm and less than or equal to 3.5 µm, etc.).

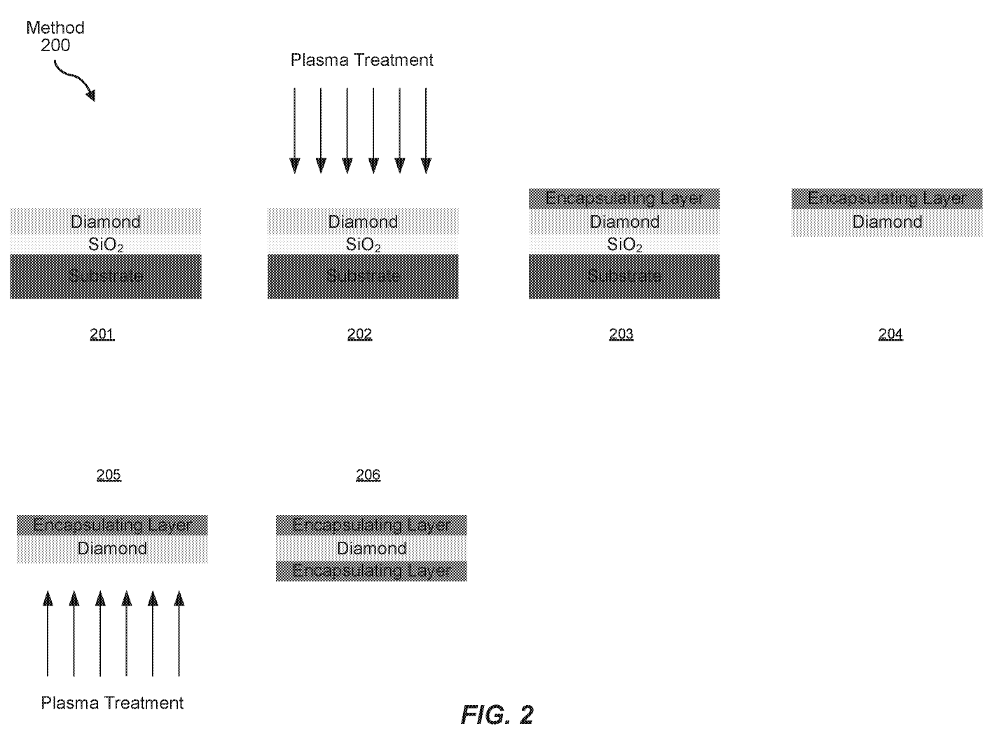

FIG. 2 is a flow diagram illustrating an example of a process 200 of fabricating a heat spreader, according to some embodiments of the subject disclosure. For instance, process 200 may be performed to produce heat spreader 100 shown in FIG. 1.

In step 201, a layer of diamond (e.g., diamond layer 110) is grown on a layer of SiO₂ on a substrate. The substrate may be, or may comprise, a silicon wafer, or a layer of molybdenum. Step 201 may comprise growing the layer of diamond through vapor deposition or sputtering. The substrate may have a thickness of less than 50 µm in some cases. The surface of the diamond layer may be optionally polished before proceeding to step 202.

In step 202, plasma is applied to treat the surface of the diamond layer, as described above. In some embodiments, step 202 comprises applying an oxygen plasma to the diamond surface. As one non-limiting example, step 202 may comprise plasma treatment in a physical vapor deposition (PVD) chamber as follows. The base pressure can be less than 10-8 mbar. Oxygen (99.99%) can be introduced into the chamber via a gas flow control system. Samples are introduced by a load-lock system and placed on a holder near the center of the chamber which is capacitively coupled to a 13.56 MHz radio frequency (RF) generator. The following parameters may be used: oxygen flow 20 sccm, pressure 3.5 Pa and effective RF power 250 W. The resulting self-bias voltage as displayed at the RF generator can be about 1200 V. The plasma treatment time may be about 45s.

Without wishing to be bound by theory, step 202 may cause an oxidation process on the diamond surface as follows. First, decomposition of the diamond lattice at the surface through formation of graphite-like structures, followed by oxidation which produces phenolic OH groups that can undergo further reaction to form keto groups. These groups subsequently undergo chemical reactions with the functional group attached to the encapsulating layer resulting in formation of a strong covalent bond between the diamond and encapsulating layer. The adhesion, and as a result, the flexibility, of the encapsulated diamond layer is enhanced significantly.

Step 203 comprises depositing the encapsulating layer (e.g., encapsulating layer 120) onto the surface of the diamond layer that was treated in step 202. In some embodiments, step 203 may comprise applying pressure to the encapsulating layer to the diamond layer under heat to produce adhesion between the encapsulating layer and the diamond layer. For instance, the encapsulating layer and the diamond layer may be heated to 80-90° C and the encapsulating layer pressed onto the diamond layer with a pressure of around 10 psi. In some embodiments, step 203 may comprise spin-coating an adhesive layer onto the diamond layer, then curing the adhesive layer to form the encapsulating layer. In some embodiments, step 203 may comprise spin-coating an adhesive layer onto the diamond layer then laminating the encapsulating layer onto the spin-coated layer (e.g., as described above using heat and pressure). In some embodiments, step 203 may comprise depositing the encapsulating layer onto the diamond layer via chemical vapor deposition (CVD).

In step 204, the substrate and SiO₂ layers are removed. Due to the adhesion between the diamond layer and the encapsulating layer produced in step 203, the SiO₂ layer may be mechanically removed in step 204 since its adhesion to the diamond layer may be much less than the adhesion of the encapsulating layer to the diamond layer. In cases where the substrate is molybdenum, this substrate layer may be re-used in subsequent processes for fabricating a heat spreader using process 200 by etching away the SiO₂ layer from the molybdenum substrate. In contrast, a silicon wafer substrate may be typically discarded after use. Thus, a molybdenum substrate may have the advantage of reusability, and therefore of reduced cost.

In step 205, a plasma treatment (e.g., the same as applied in step 202) is applied to the opposing side of the diamond layer. Optionally, the lower surface of the diamond is polished before step 205 and after step 204 to improve its thermal conductivity. In step 206, a second encapsulating layer is adhered to the lower surface of the diamond layer via any of the techniques described above in relation to step 203.

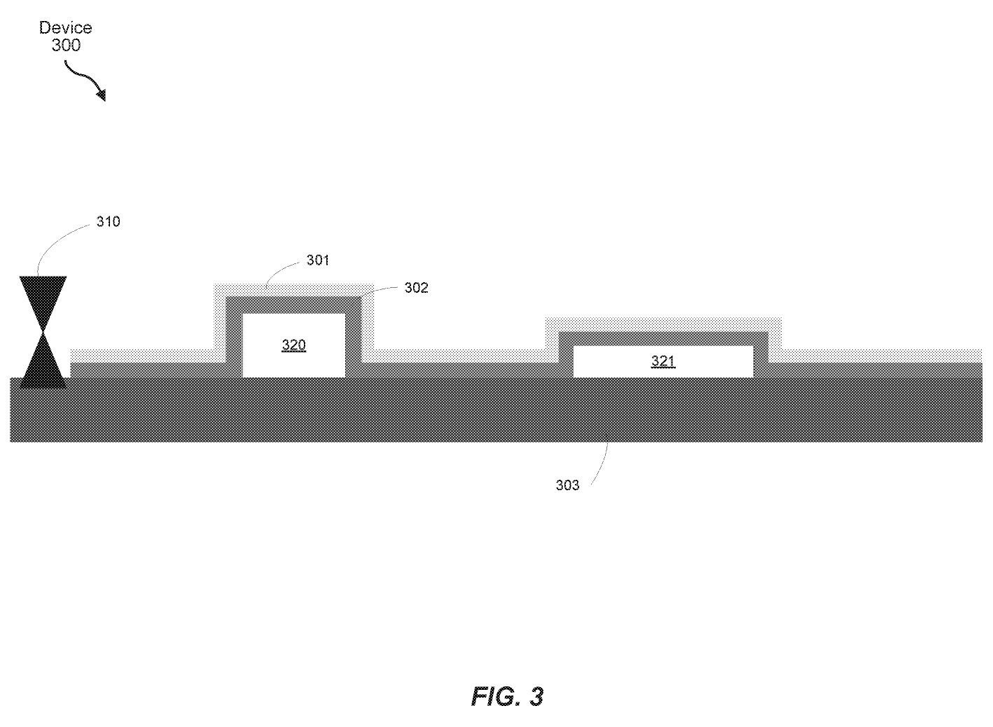

FIG. 3 is a schematic diagram illustrating a cross-sectional view of a device comprising a heat spreader, according to some embodiments of the subject disclosure. In the example of FIG. 3, device 300 comprises a substrate 303 on which a heat spreader comprising a diamond layer 301 and supporting layer 302 is arranged. The heat spreader comprising layers 301 and 302 may, for instance, be formed as heat spreader 100 shown in FIG. 1. Device 300 also includes semiconductor packages 320 and 321, which may each include any suitable semiconductor package, including electronic circuitry, a ball grid array, small outline package (SOP), system in package (SiP), etc.

According to some embodiments, the substrate 303 may be a flexible substrate, such that the device 300 is flexible. For instance, the device 300 may be a wearable, wrist-mounted device. In some embodiments, substrate 303 is, or comprises, a polymer such as polyimide or PET.

In the example of FIG. 3, device 300 includes antenna 310. As described above, the improved heat spreader comprising a flexible diamond layer as described herein may be arranged in close proximity to an antenna, unlike other heat spreaders that are electrically conductive, or that contain electrically conductive components, and are not placed near an antenna.

In some embodiments, a device of the subject technology comprises at least one semiconductor package and a flexible diamond heat spreader arranged over the at least one semiconductor package. In some embodiments, the flexible diamond heat spreader comprises a first polymer layer and a second polymer layer adhered to opposing sides of a layer of diamond.

In some embodiments, the first polymer layer and the second polymer layer each have a thickness between 30 µm and 60 µm, and the layer of diamond has a thickness between 10 µm and 40 µm. In some embodiments, a grain size of the layer of diamond is between 2.5 µm and 3.5 µm. In some embodiments, the first polymer layer and the second polymer layer each comprise a thermoplastic. In some embodiments, the first polymer layer and the second polymer layer each comprise polypropylene, polyimide and/or polyethylene terephthalate. In some embodiments, the flexible diamond heat spreader comprises a diamond layer having a thickness between 20 µm and 50 µm.

In some embodiments, a flexible diamond heat spreader comprises a laminar layer of diamond chemically adhered to a first polymer layer on a first face of the laminar layer of diamond, and chemically adhered to a second polymer layer on a second face of the laminar layer of diamond.

In some embodiments, a method of fabricating a flexible diamond heat spreader comprises forming a layer of diamond on a substrate; applying an oxygen plasma to a surface of the layer of diamond; and chemically adhering a polymer layer to the surface of the layer of diamond. In some embodiments, the layer of diamond has a thickness between 20 µm and 50 µm and wherein the polymer layer has a thickness between 30 µm and 60 µm.

Embodiments of the present disclosure may include or be implemented in conjunction with various types of AR systems. AR may be any superimposed functionality and/or sensory-detectable content presented by an AR system within a user’s physical surroundings. In other words, AR is a form of reality that has been adjusted in some manner before presentation to a user. AR can include and/or represent virtual reality (VR), augmented reality (AR), mixed AR (MAR), or some combination and/or variation of these types of realities. Similarly, AR environments may include VR environments (including non-immersive, semi-immersive, and fully immersive VR environments), augmented-reality environments (including marker-based augmented-reality environments, marker-less augmented-reality environments, location-based augmented-reality environments, and projection-based augmented-reality environments), hybrid-reality environments, and/or any other type or form of mixed- or alternative-reality environments.

AR content may include completely computer-generated content or computer-generated content combined with captured (e.g., real-world) content. Such AR content may include video, audio, haptic feedback, or some combination thereof, any of which may be presented in a single channel or in multiple channels (such as stereo video that produces a three-dimensional (3D) effect to the viewer). Additionally, in some embodiments, AR may also be associated with applications, products, accessories, services, or some combination thereof, that are used to, for example, create content in an artificial reality and/or are otherwise used in (e.g., to perform activities in) an artificial reality.

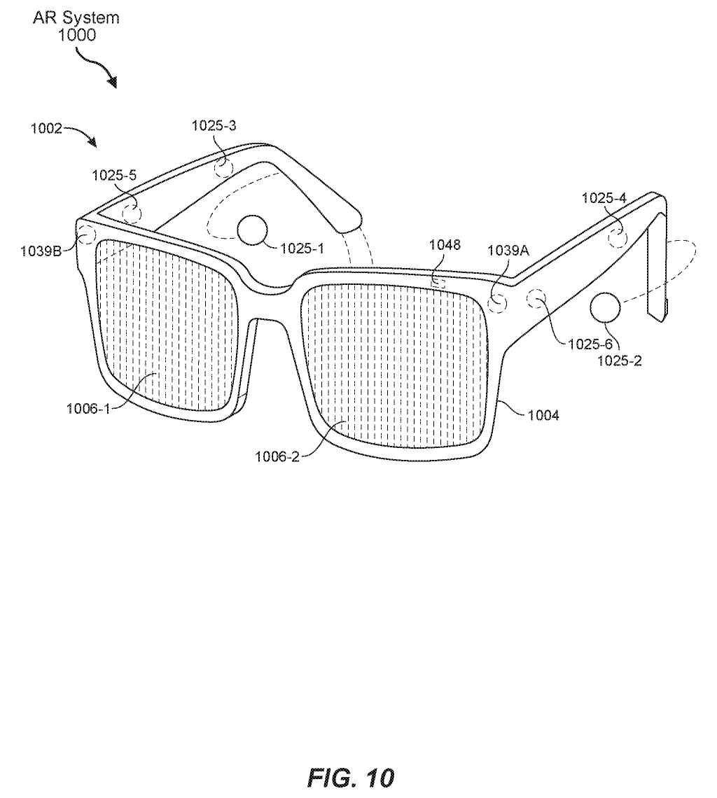

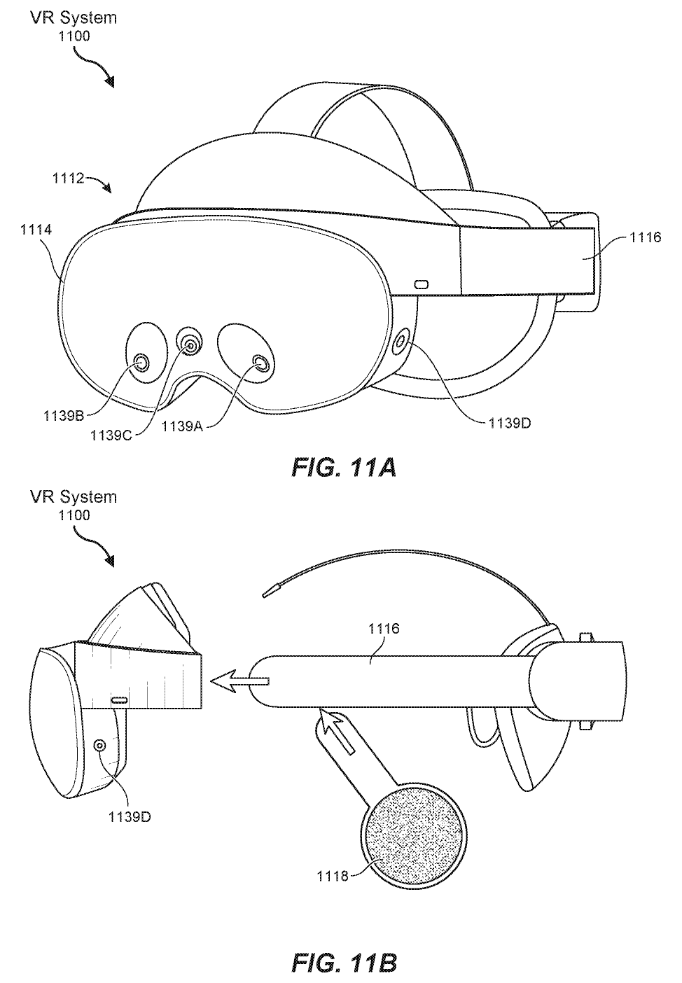

AR systems may be implemented in a variety of different form factors and configurations. Some AR systems may be designed to work without near-eye displays (NEDs). Other AR systems may include an NED that also provides visibility into the real world (such as, e.g., augmented-reality system 1000 in FIG. 10) or that visually immerses a user in an artificial reality (such as, e.g., VR system 1100 in FIGS. 11A and 11B). While some AR devices may be self-contained systems, other AR devices may communicate and/or coordinate with external devices to provide an AR experience to a user. Examples of such external devices include handheld controllers, mobile devices, desktop computers, devices worn by a user, devices worn by one or more other users, and/or any other suitable external system.

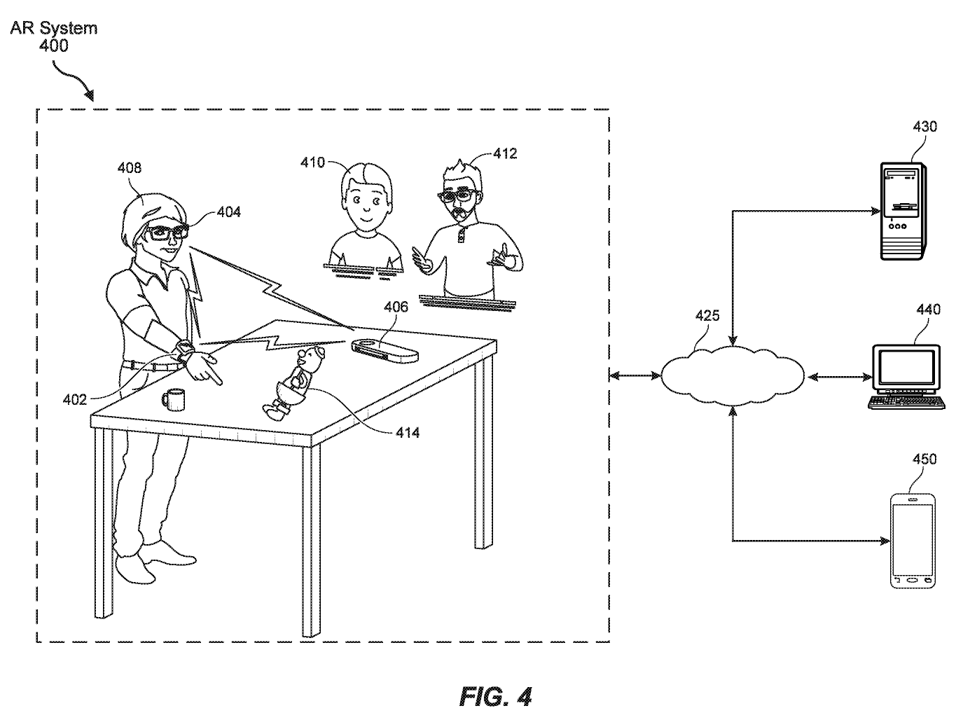

FIG. 4 is a schematic diagram illustrating an example AR system, according to some embodiments of the subject disclosure. In FIG. 4, wrist-wearable device 402, AR glasses 404, and/or HIPD 406 can communicatively couple via a network 425 (e.g., cellular, near field, Wi-Fi, personal area network, wireless LAN, etc.). Additionally, wrist-wearable device 402, AR glasses 404, and/or HIPD 406 can also communicatively couple with one or more servers 430, computers 440 (e.g., laptops, computers, etc.), mobile devices 450 (e.g., smartphones, tablets, etc.), and/or other electronic devices via network 425 (e.g., cellular, near field, Wi-Fi, personal area network, wireless LAN, etc.).

In FIG. 4, a user 408 is shown wearing wrist-wearable device 402 and AR glasses 404 and having HIPD 406 on their desk. The wrist-wearable device 402, AR glasses 404, and HIPD 406 facilitate user interaction with an AR environment. In particular, as shown by first AR system 400, wrist-wearable device 402, AR glasses 404, and/or HIPD 406 cause presentation of one or more avatars 410, digital representations of contacts 412, and virtual objects 414. As discussed below, user 408 can interact with one or more avatars 410, digital representations of contacts 412, and virtual objects 414 via wrist-wearable device 402, AR glasses 404, and/or HIPD 406.

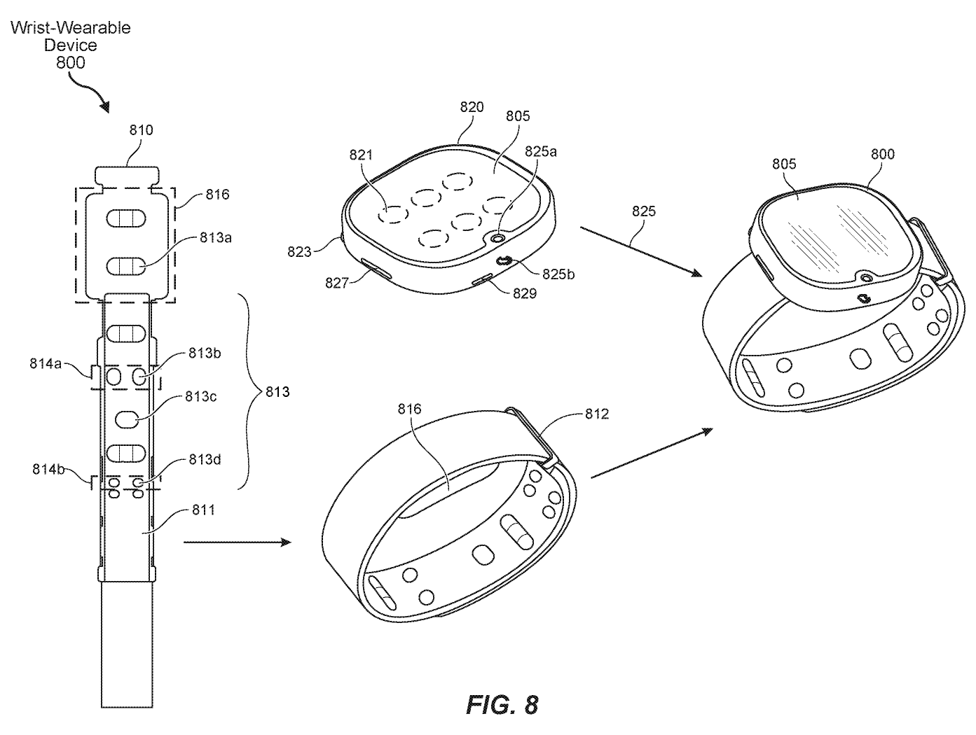

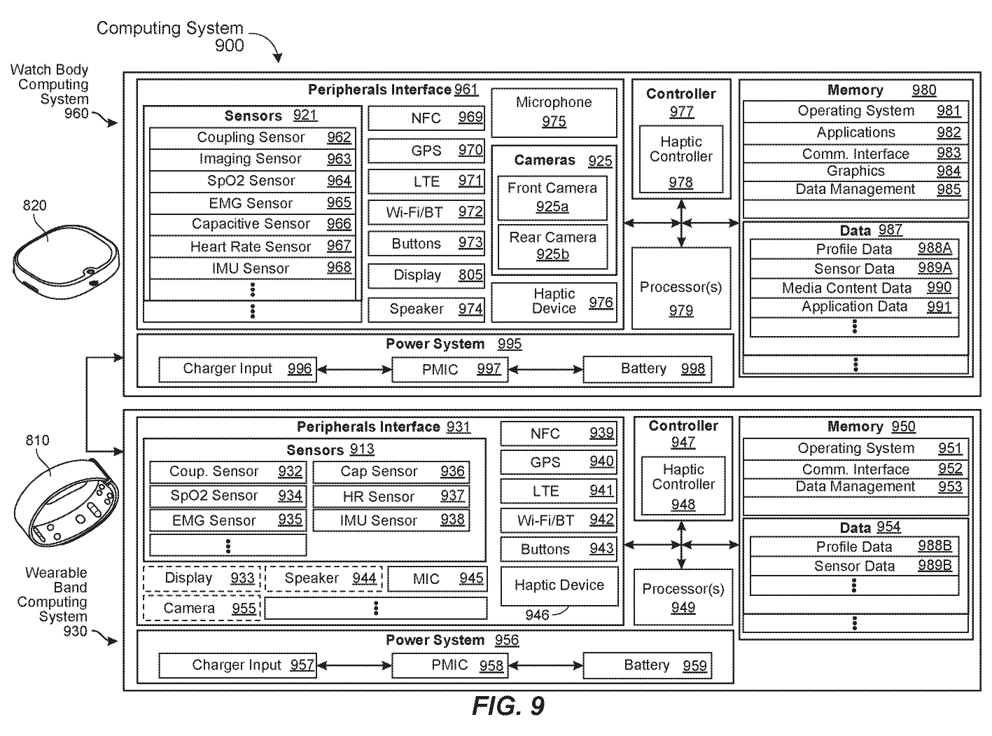

User 408 can use any of wrist-wearable device 402, AR glasses 404, and/or HIPD 406 to provide user inputs. For example, user 408 can perform one or more hand gestures that are detected by wrist-wearable device 402 (e.g., using one or more EMG sensors and/or IMUs, described below in reference to FIGS. 8 and 9) and/or AR glasses 404 (e.g., using one or more image sensors or cameras, described below in reference to FIGS. 10-12) to provide a user input. Alternatively, or additionally, user 408 can provide a user input via one or more touch surfaces of wrist-wearable device 402, AR glasses 404, HIPD 406, and/or voice commands captured by a microphone of wrist-wearable device 402, AR glasses 404, and/or HIPD 406. In some embodiments, wrist-wearable device 402, AR glasses 404, and/or HIPD 406 include a digital assistant to help user 408 in providing a user input (e.g., completing a sequence of operations, suggesting different operations or commands, providing reminders, confirming a command, etc.). In some embodiments, user 408 can provide a user input via one or more facial gestures and/or facial expressions. For example, cameras of wrist-wearable device 402, AR glasses 404, and/or HIPD 406 can track the eyes of user 408 for navigating a user interface.

Wrist-wearable device 402, AR glasses 404, and/or HIPD 406 can operate alone or in conjunction to allow user 408 to interact with the AR environment. In some embodiments, HIPD 406 is configured to operate as a central hub or control center for the wrist-wearable device 402, AR glasses 404, and/or another communicatively coupled device. For example, user 408 can provide an input to interact with the AR environment at any of wrist-wearable device 402, AR glasses 404, and/or HIPD 406, and HIPD 406 can identify one or more back-end and front-end tasks to cause the performance of the requested interaction and distribute instructions to cause the performance of the one or more back-end and front-end tasks at wrist-wearable device 402, AR glasses 404, and/or HIPD 406. In some embodiments, a back-end task is a background processing task that is not perceptible by the user (e.g., rendering content, decompression, compression, etc.), and a front-end task is a user-facing task that is perceptible to the user (e.g., presenting information to the user, providing feedback to the user, etc.). HIPD 406 can perform the back-end tasks and provide wrist-wearable device 402 and/or AR glasses 404 operational data corresponding to the performed back-end tasks such that wrist-wearable device 402 and/or AR glasses 404 can perform the front-end tasks. In this way, HIPD 406, which has more computational resources and greater thermal headroom than wrist-wearable device 402 and/or AR glasses 404, performs computationally intensive tasks and reduces the computer resource utilization and/or power usage of wrist-wearable device 402 and/or AR glasses 404.

In the example shown by first AR system 400, HIPD 406 identifies one or more back-end tasks and front-end tasks associated with a user request to initiate an AR video call with one or more other users (represented by avatar 410 and the digital representation of contact 412) and distributes instructions to cause the performance of the one or more back-end tasks and front-end tasks. In particular, HIPD 406 performs back-end tasks for processing and/or rendering image data (and other data) associated with the AR video call and provides operational data associated with the performed back-end tasks to AR glasses 404 such that the AR glasses 404 perform front-end tasks for presenting the AR video call (e.g., presenting avatar 410 and digital representation of contact 412).

In some embodiments, HIPD 406 can operate as a focal or anchor point for causing the presentation of information. This allows user 408 to be generally aware of where information is presented. For example, as shown in first AR system 400, avatar 410 and the digital representation of contact 412 are presented above HIPD 406. In particular, HIPD 406 and AR glasses 404 operate in conjunction to determine a location for presenting avatar 410 and the digital representation of contact 412. In some embodiments, information can be presented a predetermined distance from HIPD 406 (e.g., within 5 meters). For example, as shown in first AR system 400, virtual object 414 is presented on the desk some distance from HIPD 406. Similar to the above example, HIPD 406 and AR glasses 404 can operate in conjunction to determine a location for presenting virtual object 414. Alternatively, in some embodiments, presentation of information is not bound by HIPD 406. More specifically, avatar 410, digital representation of contact 412, and virtual object 414 do not have to be presented within a predetermined distance of HIPD 406.

User inputs provided at wrist-wearable device 402, AR glasses 404, and/or HIPD 406 are coordinated such that the user can use any device to initiate, continue, and/or complete an operation. For example, user 408 can provide a user input to AR glasses 404 to cause AR glasses 404 to present virtual object 414 and, while virtual object 414 is presented by AR glasses 404, user 408 can provide one or more hand gestures via wrist-wearable device 402 to interact and/or manipulate virtual object 414.

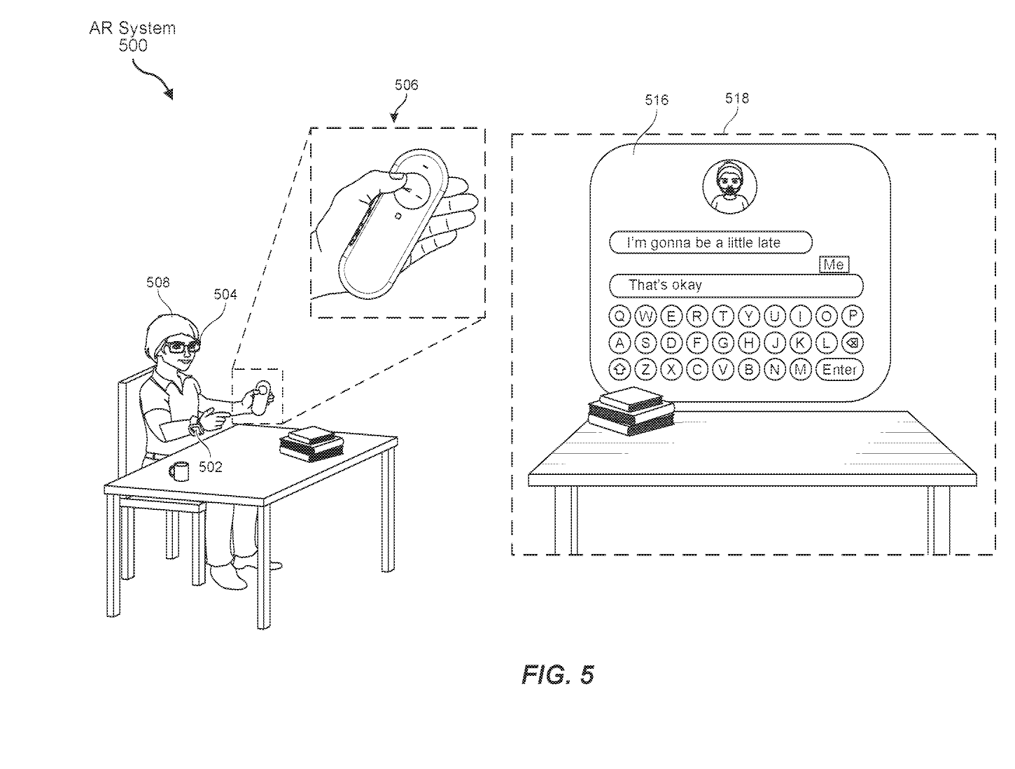

FIG. 5 is a schematic diagram illustrating an example AR system with a handheld device, according to some embodiments of the subject disclosure. In FIG. 5, a user 508 is shown wearing a wrist-wearable device 502 and AR glasses 504, and holding an HIPD 506. In second AR system 500, the wrist-wearable device 502, AR glasses 504, and/or HIPD 506 are used to receive and/or provide one or more messages to a contact of user 508. In particular, wrist-wearable device 502, AR glasses 504, and/or HIPD 506 detect and coordinate one or more user inputs to initiate a messaging application and prepare a response to a received message via the messaging application.

In some embodiments, user 508 initiates, via a user input, an application on wrist-wearable device 502, AR glasses 504, and/or HIPD 506 that causes the application to initiate on at least one device. For example, in second AR system 500, user 508 performs a hand gesture associated with a command for initiating a messaging application (represented by messaging user interface 516), wrist-wearable device 502 detects the hand gesture and, based on a determination that user 508 is wearing AR glasses 504, causes AR glasses 504 to present a messaging user interface 516 of the messaging application. AR glasses 504 can present messaging user interface 516 to user 508 via its display (e.g., as shown by a field of view 518 of user 508). In some embodiments, the application is initiated and executed on the device (e.g., wrist-wearable device 502, AR glasses 504, and/or HIPD 506) that detects the user input to initiate the application, and the device provides another device operational data to cause the presentation of the messaging application. For example, wrist-wearable device 502 can detect the user input to initiate a messaging application, initiate and run the messaging application, and provide operational data to AR glasses 504 and/or HIPD 506 to cause presentation of the messaging application. Alternatively, the application can be initiated and executed at a device other than the device that detected the user input. For example, wrist-wearable device 502 can detect the hand gesture associated with initiating the messaging application and cause HIPD 506 to run the messaging application and coordinate the presentation of the messaging application.

Further, user 508 can provide a user input provided at wrist-wearable device 502, AR glasses 504, and/or HIPD 506 to continue and/or complete an operation initiated at another device. For example, after initiating the messaging application via wrist-wearable device 502 and while AR glasses 504 present messaging user interface 516, user 508 can provide an input at HIPD 506 to prepare a response (e.g., shown by the swipe gesture performed on HIPD 506). Gestures performed by user 508 on HIPD 506 can be provided and/or displayed on another device. For example, a swipe gestured performed on HIPD 506 is displayed on a virtual keyboard of messaging user interface 516 displayed by AR glasses 504.

In some embodiments, wrist-wearable device 502, AR glasses 504, HIPD 506, and/or any other communicatively coupled device can present one or more notifications to user 508. The notification can be an indication of a new message, an incoming call, an application update, a status update, etc. User 508 can select the notification via wrist-wearable device 502, AR glasses 504, and/or HIPD 506 and can cause presentation of an application or operation associated with the notification on at least one device. For example, user 508 can receive a notification that a message was received at wrist-wearable device 502, AR glasses 504, HIPD 506, and/or any other communicatively coupled device and can then provide a user input at wrist-wearable device 502, AR glasses 504, and/or HIPD 506 to review the notification, and the device detecting the user input can cause an application associated with the notification to be initiated and/or presented at wrist-wearable device 502, AR glasses 504, and/or HIPD 506.

While the above example describes coordinated inputs used to interact with a messaging application, user inputs can be coordinated to interact with any number of applications including, but not limited to, gaming applications, social media applications, camera applications, web-based applications, financial applications, etc. For example, AR glasses 504 can present to user 508 game application data, and HIPD 506 can be used as a controller to provide inputs to the game. Similarly, user 508 can use wrist-wearable device 502 to initiate a camera of AR glasses 504, and user 508 can use wrist-wearable device 502, AR glasses 504, and/or HIPD 506 to manipulate the image capture (e.g., zoom in or out, apply filters, etc.) and capture image data.

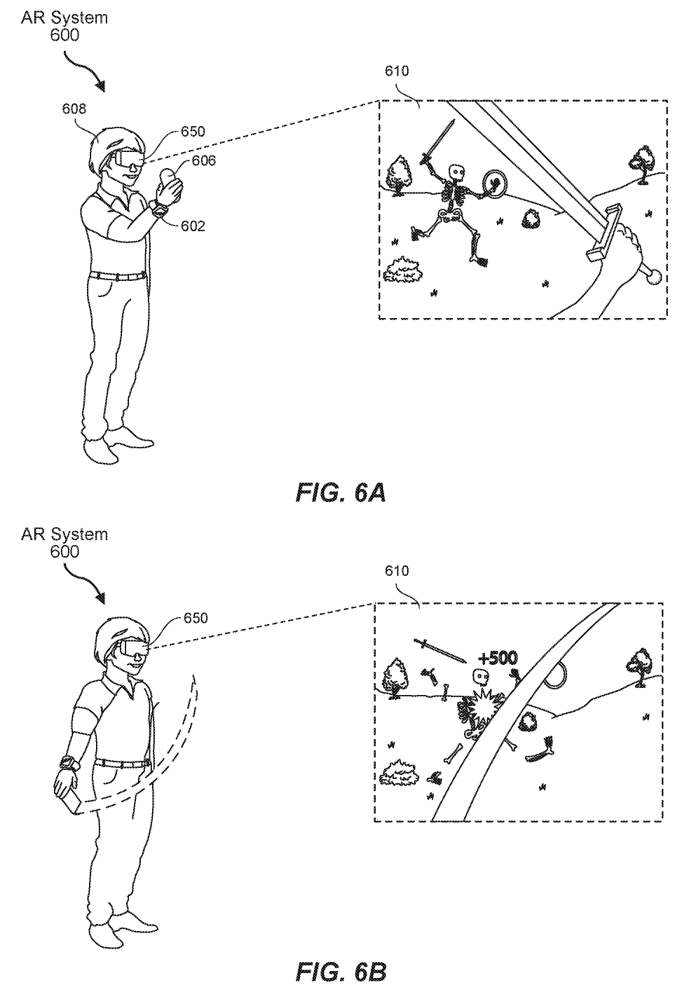

FIGS. 6A and 6B are schematic diagrams illustrating examples of user interactions within an AR system, according to some embodiments of the subject disclosure. Users may interact with the devices disclosed herein in a variety of ways. For example, as shown in FIGS. 6A and 6B, a user 608 may interact with an AR system 600 by donning a VR headset 650 while holding HIPD 606 and wearing wrist-wearable device 602. In this example, AR system 600 may enable a user to interact with a game 610 by swiping their arm. One or more of VR headset 650, HIPD 606, and wrist-wearable device 602 may detect this gesture and, in response, may display a sword strike in game 610.

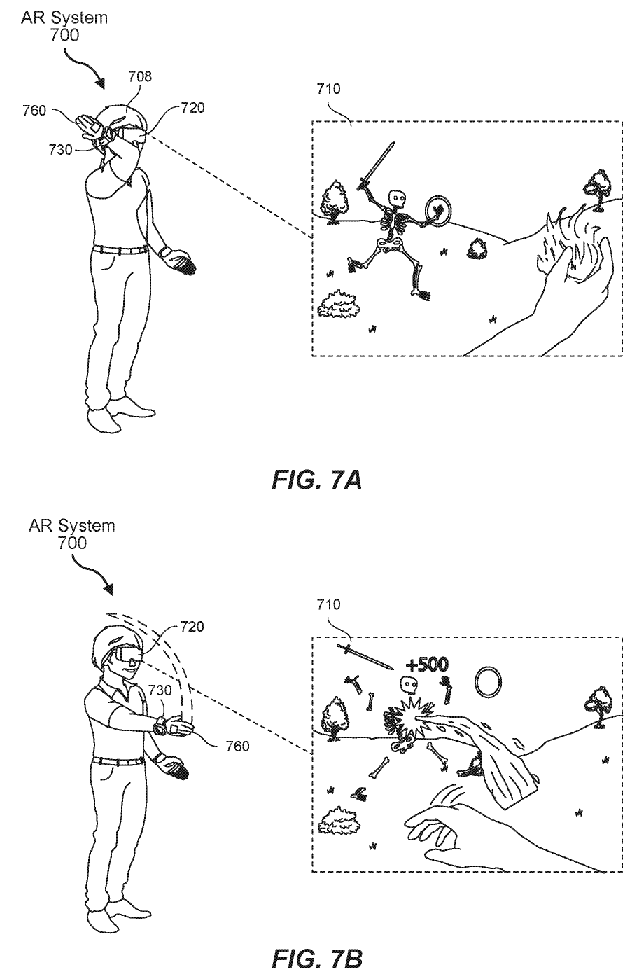

FIGS. 7A and 7B are schematic diagrams illustrating examples of user interactions within an AR system, according to some embodiments of the subject disclosure. In FIGS. 7A and 7B, a user 708 may interact with an AR system 700 by donning a VR headset 720 while wearing haptic device 760 and wrist-wearable device 730. In this example, AR system 700 may enable a user to interact with a game 710 by swiping their arm. One or more of VR headset 720, haptic device 760, and wrist-wearable device 730 may detect this gesture and, in response, may display a spell being cast in game 710.

Having discussed example AR systems, devices for interacting with such AR systems and other computing systems more generally will now be discussed in greater detail. Some explanations of devices and components that can be included in some or all of the example devices discussed below are explained herein for ease of reference. Certain types of the components described below may be more suitable for a particular set of devices, and less suitable for a different set of devices. But subsequent reference to the components explained here should be considered to be encompassed by the descriptions provided.

In some embodiments discussed below, example devices and systems, including electronic devices and systems, will be addressed. Such example devices and systems are not intended to be limiting, and one of skill in the art will understand that alternative devices and systems to the example devices and systems described herein may be used to perform the operations and construct the systems and devices that are described herein.

An electronic device may be a device that uses electrical energy to perform a specific function. An electronic device can be any physical object that contains electronic components such as transistors, resistors, capacitors, diodes, and integrated circuits. Examples of electronic devices include smartphones, laptops, digital cameras, televisions, gaming consoles, and music players, as well as the example electronic devices discussed herein. As described herein, an intermediary electronic device may be a device that sits between two other electronic devices and/or a subset of components of one or more electronic devices and facilitates communication, data processing, and/or data transfer between the respective electronic devices and/or electronic components.

An integrated circuit may be an electronic device made up of multiple interconnected electronic components such as transistors, resistors, and capacitors. These components may be etched onto a small piece of semiconductor material, such as silicon. Integrated circuits may include analog integrated circuits, digital integrated circuits, mixed signal integrated circuits, and/or any other suitable type or form of integrated circuit. Examples of integrated circuits include application-specific integrated circuits (ASICs), processing units, central processing units (CPUs), co-processors, and accelerators.

Analog integrated circuits, such as sensors, power management circuits, and operational amplifiers, may process continuous signals and perform analog functions such as amplification, active filtering, demodulation, and mixing. Examples of analog integrated circuits include linear integrated circuits and radio frequency circuits.

Digital integrated circuits, which may be referred to as logic integrated circuits, may include microprocessors, microcontrollers, memory chips, interfaces, power management circuits, programmable devices, and/or any other suitable type or form of integrated circuit. In some embodiments, examples of integrated circuits include central processing units (CPUs),

Processing units, such as CPUs, may be electronic components that are responsible for executing instructions and controlling the operation of an electronic device (e.g., a computer). There are various types of processors that may be used interchangeably, or may be specifically required, by embodiments described herein. For example, a processor may be: (i) a general processor designed to perform a wide range of tasks, such as running software applications, managing operating systems, and performing arithmetic and logical operations; (ii) a microcontroller designed for specific tasks such as controlling electronic devices, sensors, and motors; (iii) an accelerator, such as a graphics processing unit (GPU), designed to accelerate the creation and rendering of images, videos, and animations (e.g., VR animations, such as three-dimensional modeling); (iv) a field-programmable gate array (FPGA) that can be programmed and reconfigured after manufacturing and/or can be customized to perform specific tasks, such as signal processing, cryptography, and machine learning; and/or (v) a digital signal processor (DSP) designed to perform mathematical operations on signals such as audio, video, and radio waves. One or more processors of one or more electronic devices may be used in various embodiments described herein.

Controllers may be electronic components that manage and coordinate the operation of other components within an electronic device (e.g., controlling inputs, processing data, and/or generating outputs). Examples of controllers can include: (i) microcontrollers, including small, low-power controllers that are commonly used in embedded systems and Internet of Things (IoT) devices; (ii) programmable logic controllers (PLCs) that may be configured to be used in industrial automation systems to control and monitor manufacturing processes; (iii) system-on-a-chip (SoC) controllers that integrate multiple components such as processors, memory, I/O interfaces, and other peripherals into a single chip; and/or (iv) DSPs.

Sensors may be electronic components (e.g., in and/or otherwise in electronic communication with electronic devices, such as wearable devices) configured to detect physical and environmental changes and generate electrical signals. Examples of sensors can include (i) imaging sensors for collecting imaging data (e.g., including one or more cameras disposed on a respective electronic device), (ii) biopotential-signal sensors, (iii) inertial measurement units (e.g., IMUs) for detecting, for example, angular rate, force, magnetic field, and/or changes in acceleration, (iv) heart rate sensors for measuring a user’s heart rate, (v) SpO2 sensors for measuring blood oxygen saturation and/or other biometric data of a user, (vi) capacitive sensors for detecting changes in potential at a portion of a user’s body (e.g., a sensor-skin interface), and/or (vii) light sensors (e.g., time-of-flight sensors, infrared light sensors, visible light sensors, etc.).

Biopotential-signal-sensing components may be devices used to measure electrical activity within the body (e.g., biopotential-signal sensors). Some types of biopotential-signal sensors include (i) electroencephalography (EEG) sensors configured to measure electrical activity in the brain to diagnose neurological disorders, (ii) electrocardiography (ECG or EKG) sensors configured to measure electrical activity of the heart to diagnose heart problems, (iii) electromyography (EMG) sensors configured to measure the electrical activity of muscles and to diagnose neuromuscular disorders, and (iv) electrooculography (EOG) sensors configured to measure the electrical activity of eye muscles to detect eye movement and diagnose eye disorders.

Non-transitory computer-readable storage media may be physical devices or storage media that can be used to store electronic data in a non-transitory form (e.g., such that the data is stored permanently until it is intentionally deleted or modified).

FIG. 8 is an illustration of an example wrist-wearable device 800 of an AR system, according to some embodiments of the subject disclosure. FIG. 8 shows a wearable band 810 and a watch body 820 (or capsule) being coupled, as discussed below, to form wrist-wearable device 800. Wrist-wearable device 800 can perform various functions and/or operations associated with navigating through user interfaces and selectively opening applications as well as the functions and/or operations described above with reference to FIGS. 4-7B.

As will be described in more detail below, operations executed by wrist-wearable device 800 can include (i) presenting content to a user (e.g., displaying visual content via a display 805), (ii) detecting (e.g., sensing) user input (e.g., sensing a touch on peripheral button 823 and/or at a touch screen of the display 805, a hand gesture detected by sensors (e.g., biopotential sensors)), and (iii) sensing biometric data (e.g., neuromuscular signals, heart rate, temperature, sleep, etc.) via one or more sensors 813, messaging (e.g., text, speech, video, etc.), image capture via one or more imaging devices or cameras 825, wireless communications (e.g., cellular, near field, Wi-Fi, personal area network, etc.), location determination, financial transactions, providing haptic feedback, providing alarms, providing notifications, providing biometric authentication, providing health monitoring, providing sleep monitoring, etc.

The above-example functions can be executed independently in watch body 820, independently in wearable band 810, and/or via an electronic communication between watch body 820 and wearable band 810. In some embodiments, functions can be executed on wrist-wearable device 800 while an AR environment is being presented (e.g., via one of AR systems 400 to 700). The wearable devices described herein can also be used with other types of AR environments.

Wearable band 810 can be configured to be worn by a user such that an inner surface of a wearable structure 811 of wearable band 810 is in contact with the user’s skin. In this example, when worn by a user, sensors 813 may contact the user’s skin. In some examples, one or more of sensors 813 can sense biometric data such as a user’s heart rate, a saturated oxygen level, temperature, sweat level, neuromuscular signals, or a combination thereof. One or more of sensors 813 can also sense data about a user’s environment including a user’s motion, altitude, location, orientation, gait, acceleration, position, or a combination thereof. In some embodiments, one or more of sensors 813 can be configured to track a position and/or motion of wearable band 810. One or more of sensors 813 can include any of the sensors defined above and/or discussed below with respect to FIG. 8.

One or more of sensors 813 can be distributed on an inside and/or an outside surface of wearable band 810. In some embodiments, one or more of sensors 813 are uniformly spaced along wearable band 810. Alternatively, in some embodiments, one or more of sensors 813 are positioned at distinct points along wearable band 810. As shown in FIG. 8, one or more of sensors 813 can be the same or distinct. For example, in some embodiments, one or more of sensors 813 can be shaped as a pill (e.g., sensor 813a), an oval, a circle, a square, an oblong (e.g., sensor 813c) and/or any other shape that maintains contact with the user’s skin (e.g., such that neuromuscular signals and/or other biometric data can be accurately measured at the user’s skin). In some embodiments, one or more sensors of 813 are aligned to form pairs of sensors (e.g., for sensing neuromuscular signals based on differential sensing within each respective sensor). For example, sensor 813b may be aligned with an adjacent sensor to form sensor pair 814a and sensor 813d may be aligned with an adjacent sensor to form sensor pair 814b. In some embodiments, wearable band 810 does not have a sensor pair. Alternatively, in some embodiments, wearable band 810 has a predetermined number of sensor pairs (one pair of sensors, three pairs of sensors, four pairs of sensors, six pairs of sensors, sixteen pairs of sensors, etc.).

Wearable band 810 can include any suitable number of sensors 813. In some embodiments, the number and arrangement of sensors 813 depends on the particular application for which wearable band 810 is used. For instance, wearable band 810 can be configured as an armband, wristband, or chest-band that includes a plurality of sensors 813 with a different number of sensors 813, a variety of types of individual sensors with the plurality of sensors 813, and different arrangements for each use case, such as medical use cases as compared to gaming or general day-to-day use cases.

In accordance with some embodiments, wearable band 810 further includes an electrical ground electrode and a shielding electrode. The electrical ground and shielding electrodes, like the sensors 813, can be distributed on the inside surface of the wearable band 810 such that they contact a portion of the user’s skin. For example, the electrical ground and shielding electrodes can be at an inside surface of a coupling mechanism 816 or an inside surface of a wearable structure 811. The electrical ground and shielding electrodes can be formed and/or use the same components as sensors 813. In some embodiments, wearable band 810 includes more than one electrical ground electrode and more than one shielding electrode.

Sensors 813 can be formed as part of wearable structure 811 of wearable band 810. In some embodiments, sensors 813 are flush or substantially flush with wearable structure 811 such that they do not extend beyond the surface of wearable structure 811. While flush with wearable structure 811, sensors 813 are still configured to contact the user’s skin (e.g., via a skin-contacting surface). Alternatively, in some embodiments, sensors 813 extend beyond wearable structure 811 a predetermined distance (e.g., 0.1 – 2 mm) to make contact and depress into the user’s skin. In some embodiments, sensors 813 are coupled to an actuator (not shown) configured to adjust an extension height (e.g., a distance from the surface of wearable structure 811) of sensors 813 such that sensors 813 make contact and depress into the user’s skin. In some embodiments, the actuators adjust the extension height between 0.01 mm – 1.2 mm. This may allow the user to customize the positioning of sensors 813 to improve the overall comfort of the wearable band 810 when worn while still allowing sensors 813 to contact the user’s skin. In some embodiments, sensors 813 are indistinguishable from wearable structure 811 when worn by the user.

Wearable structure 811 can be formed of an elastic material, elastomers, etc., configured to be stretched and fitted to be worn by the user. In some embodiments, wearable structure 811 is a textile or woven fabric. As described above, sensors 813 can be formed as part of a wearable structure 811. For example, sensors 813 can be molded into the wearable structure 811, or be integrated into a woven fabric (e.g., sensors 813 can be sewn into the fabric and mimic the pliability of fabric and/or can be constructed from a series of woven strands of fabric).

Wearable structure 811 can include flexible electronic connectors that interconnect sensors 813, the electronic circuitry, and/or other electronic components (described below in reference to FIG. 9) that are enclosed in wearable band 810. In some embodiments, the flexible electronic connectors are configured to interconnect sensors 813, the electronic circuitry, and/or other electronic components of wearable band 810 with respective sensors and/or other electronic components of another electronic device (e.g., watch body 820). The flexible electronic connectors are configured to move with wearable structure 811 such that the user adjustment to wearable structure 811 (e.g., resizing, pulling, folding, etc.) does not stress or strain the electrical coupling of components of wearable band 810.

As described above, wearable band 810 is configured to be worn by a user. In particular, wearable band 810 can be shaped or otherwise manipulated to be worn by a user. For example, wearable band 810 can be shaped to have a substantially circular shape such that it can be configured to be worn on the user’s lower arm or wrist. Alternatively, wearable band 810 can be shaped to be worn on another body part of the user, such as the user’s upper arm (e.g., around a bicep), forearm, chest, legs, etc. Wearable band 810 can include a retaining mechanism 812 (e.g., a buckle, a hook and loop fastener, etc.) for securing wearable band 810 to the user’s wrist or other body part. While wearable band 810 is worn by the user, sensors 813 sense data (referred to as sensor data) from the user’s skin. In some examples, sensors 813 of wearable band 810 obtain (e.g., sense and record) neuromuscular signals.

The sensed data (e.g., sensed neuromuscular signals) can be used to detect and/or determine the user’s intention to perform certain motor actions. In some examples, sensors 813 may sense and record neuromuscular signals from the user as the user performs muscular activations (e.g., movements, gestures, etc.). The detected and/or determined motor actions (e.g., phalange (or digit) movements, wrist movements, hand movements, and/or other muscle intentions) can be used to determine control commands or control information (instructions to perform certain commands after the data is sensed) for causing a computing device to perform one or more input commands. For example, the sensed neuromuscular signals can be used to control certain user interfaces displayed on display 805 of wrist-wearable device 800 and/or can be transmitted to a device responsible for rendering an AR environment (e.g., a head-mounted display) to perform an action in an associated AR environment, such as to control the motion of a virtual device displayed to the user. The muscular activations performed by the user can include static gestures, such as placing the user’s hand palm down on a table, dynamic gestures, such as grasping a physical or virtual object, and covert gestures that are imperceptible to another person, such as slightly tensing a joint by co-contracting opposing muscles or using sub-muscular activations. The muscular activations performed by the user can include symbolic gestures (e.g., gestures mapped to other gestures, interactions, or commands, for example, based on a gesture vocabulary that specifies the mapping of gestures to commands).

The sensor data sensed by sensors 813 can be used to provide a user with an enhanced interaction with a physical object (e.g., devices communicatively coupled with wearable band 810) and/or a virtual object in an AR application generated by an AR system (e.g., user interface objects presented on the display 805, or another computing device (e.g., a smartphone)).

In some embodiments, wearable band 810 includes one or more haptic devices 946 (e.g., a vibratory haptic actuator) that are configured to provide haptic feedback (e.g., a cutaneous and/or kinesthetic sensation, etc.) to the user’s skin. Sensors 813 and/or haptic devices 946 (shown in FIG. 9) can be configured to operate in conjunction with multiple applications including, without limitation, health monitoring, social media, games, and artificial reality (e.g., the applications associated with artificial reality).

Wearable band 810 can also include coupling mechanism 816 for detachably coupling a capsule (e.g., a computing unit) or watch body 820 (via a coupling surface of the watch body 820) to wearable band 810. For example, a cradle or a shape of coupling mechanism 816 can correspond to shape of watch body 820 of wrist-wearable device 800. In particular, coupling mechanism 816 can be configured to receive a coupling surface proximate to the bottom side of watch body 820 (e.g., a side opposite to a front side of watch body 820 where display 805 is located), such that a user can push watch body 820 downward into coupling mechanism 816 to attach watch body 820 to coupling mechanism 816. In some embodiments, coupling mechanism 816 can be configured to receive a top side of the watch body 820 (e.g., a side proximate to the front side of watch body 820 where display 805 is located) that is pushed upward into the cradle, as opposed to being pushed downward into coupling mechanism 816. In some embodiments, coupling mechanism 816 is an integrated component of wearable band 810 such that wearable band 810 and coupling mechanism 816 are a single unitary structure. In some embodiments, coupling mechanism 816 is a type of frame or shell that allows watch body 820’s coupling surface to be retained within or on wearable band 810 coupling mechanism 816 (e.g., a cradle, a tracker band, a support base, a clasp, etc.).

Coupling mechanism 816 can allow for watch body 820 to be detachably coupled to the wearable band 810 through a friction fit, magnetic coupling, a rotation-based connector, a shear-pin coupler, a retention spring, one or more magnets, a clip, a pin shaft, a hook and loop fastener, or a combination thereof. A user can perform any type of motion to couple the watch body 820 to wearable band 810 and to decouple the watch body 820 from the wearable band 810. For example, a user can twist, slide, turn, push, pull, or rotate watch body 820 relative to wearable band 810, or a combination thereof, to attach watch body 820 to wearable band 810 and to detach watch body 820 from wearable band 810. Alternatively, as discussed below, in some embodiments, the watch body 820 can be decoupled from the wearable band 810 by actuation of a release mechanism 829.

Wearable band 810 can be coupled with watch body 820 to increase the functionality of wearable band 810 (e.g., converting wearable band 810 into wrist-wearable device 800, adding an additional computing unit and/or battery to increase computational resources and/or a battery life of wearable band 810, adding additional sensors to improve sensed data, etc.). As described above, wearable band 810 and coupling mechanism 816 are configured to operate independently (e.g., execute functions independently) from watch body 820. For example, coupling mechanism 816 can include one or more sensors 813 that contact a user’s skin when wearable band 810 is worn by the user, with or without watch body 820 and can provide sensor data for determining control commands.

A user can detach watch body 820 from wearable band 810 to reduce the encumbrance of wrist-wearable device 800 to the user. For embodiments in which watch body 820 is removable, watch body 820 can be referred to as a removable structure, such that in these embodiments wrist-wearable device 800 includes a wearable portion (e.g., wearable band 810) and a removable structure (e.g., watch body 820).

Turning to watch body 820, in some examples, watch body 820 can have a substantially rectangular or circular shape. Watch body 820 is configured to be worn by the user on their wrist or on another body part. More specifically, watch body 820 is sized to be easily carried by the user, attached on a portion of the user’s clothing, and/or coupled to wearable band 810 (forming the wrist-wearable device 800). As described above, watch body 820 can have a shape corresponding to coupling mechanism 816 of wearable band 810. In some embodiments, watch body 820 includes a single release mechanism 829 or multiple release mechanisms (e.g., two release mechanisms 829 positioned on opposing sides of watch body 820, such as spring-loaded buttons) for decoupling watch body 820 from wearable band 810. Release mechanism 829 can include, without limitation, a button, a knob, a plunger, a handle, a lever, a fastener, a clasp, a dial, a latch, or a combination thereof.

A user can actuate release mechanism 829 by pushing, turning, lifting, depressing, shifting, or performing other actions on release mechanism 829. Actuation of release mechanism 829 can release (e.g., decouple) watch body 820 from coupling mechanism 816 of wearable band 810, allowing the user to use watch body 820 independently from wearable band 810 and vice versa. For example, decoupling watch body 820 from wearable band 810 can allow a user to capture images using rear-facing camera 825b. Although release mechanism 829 is shown positioned at a corner of watch body 820, release mechanism 829 can be positioned anywhere on watch body 820 that is convenient for the user to actuate. In addition, in some embodiments, wearable band 810 can also include a respective release mechanism for decoupling watch body 820 from coupling mechanism 816. In some embodiments, release mechanism 829 is optional and watch body 820 can be decoupled from coupling mechanism 816 as described above (e.g., via twisting, rotating, etc.).

Watch body 820 can include one or more peripheral buttons 823 and 827 for performing various operations at watch body 820. For example, peripheral buttons 823 and 827 can be used to turn on or wake (e.g., transition from a sleep state to an active state) display 805, unlock watch body 820, increase or decrease a volume, increase or decrease a brightness, interact with one or more applications, interact with one or more user interfaces, etc. Additionally or alternatively, in some embodiments, display 805 operates as a touch screen and allows the user to provide one or more inputs for interacting with watch body 820.

In some embodiments, watch body 820 includes one or more sensors 821. Sensors 821 of watch body 820 can be the same or distinct from sensors 813 of wearable band 810. Sensors 821 of watch body 820 can be distributed on an inside and/or an outside surface of watch body 820. In some embodiments, sensors 821 are configured to contact a user’s skin when watch body 820 is worn by the user. For example, sensors 821 can be placed on the bottom side of watch body 820 and coupling mechanism 816 can be a cradle with an opening that allows the bottom side of watch body 820 to directly contact the user’s skin. Alternatively, in some embodiments, watch body 820 does not include sensors that are configured to contact the user’s skin (e.g., including sensors internal and/or external to the watch body 820 that are configured to sense data of watch body 820 and the surrounding environment). In some embodiments, sensors 821 are configured to track a position and/or motion of watch body 820.

Watch body 820 and wearable band 810 can share data using a wired communication method (e.g., a Universal Asynchronous Receiver/Transmitter (UART), a USB transceiver, etc.) and/or a wireless communication method (e.g., near field communication, Bluetooth, etc.). For example, watch body 820 and wearable band 810 can share data sensed by sensors 813 and 821, as well as application and device specific information (e.g., active and/or available applications, output devices (e.g., displays, speakers, etc.), input devices (e.g., touch screens, microphones, imaging sensors, etc.)).

In some embodiments, watch body 820 can include, without limitation, a front-facing camera 825a and/or a rear-facing camera 825b, sensors 821 (e.g., a biometric sensor, an IMU, a heart rate sensor, a saturated oxygen sensor, a neuromuscular signal sensor, an altimeter sensor, a temperature sensor, a bioimpedance sensor, a pedometer sensor, an optical sensor (e.g., imaging sensor 963), a touch sensor, a sweat sensor, etc.). In some embodiments, watch body 820 can include one or more haptic devices 976 (e.g., a vibratory haptic actuator) that is configured to provide haptic feedback (e.g., a cutaneous and/or kinesthetic sensation, etc.) to the user. Sensors 921 and/or haptic device 976 can also be configured to operate in conjunction with multiple applications including, without limitation, health monitoring applications, social media applications, game applications, and artificial reality applications (e.g., the applications associated with artificial reality).

As described above, watch body 820 and wearable band 810, when coupled, can form wrist-wearable device 800. When coupled, watch body 820 and wearable band 810 may operate as a single device to execute functions (operations, detections, communications, etc.) described herein. In some embodiments, each device may be provided with particular instructions for performing the one or more operations of wrist-wearable device 800. For example, in accordance with a determination that watch body 820 does not include neuromuscular signal sensors, wearable band 810 can include alternative instructions for performing associated instructions (e.g., providing sensed neuromuscular signal data to watch body 820 via a different electronic device). Operations of wrist-wearable device 800 can be performed by watch body 820 alone or in conjunction with wearable band 810 (e.g., via respective processors and/or hardware components) and vice versa. In some embodiments, operations of wrist-wearable device 800, watch body 820, and/or wearable band 810 can be performed in conjunction with one or more processors and/or hardware components.

As described below with reference to the block diagram of FIG. 9, wearable band 810 and/or watch body 820 can each include independent resources required to independently execute functions. For example, wearable band 810 and/or watch body 820 can each include a power source (e.g., a battery), a memory, data storage, a processor (e.g., a central processing unit (CPU)), communications, a light source, and/or input/output devices.

FIG. 9 is a block diagram illustrating an example of a wearable AR system 900, according to some embodiments of the subject disclosure. The block diagram shown in FIG. 9 includes a block diagram of a computing system 930 corresponding to wearable band 810 and a computing system 960 corresponding to watch body 820, according to some embodiments. Computing system 900 of wrist-wearable device 800 may include a combination of components of wearable band computing system 930 and watch body computing system 960, in accordance with some embodiments.

Watch body 820 and/or wearable band 810 can include one or more components shown in watch body computing system 960. In some embodiments, a single integrated circuit may include all or a substantial portion of the components of watch body computing system 960 included in a single integrated circuit. Alternatively, in some embodiments, components of the watch body computing system 960 may be included in a plurality of integrated circuits that are communicatively coupled. In some embodiments, watch body computing system 960 may be configured to couple (e.g., via a wired or wireless connection) with wearable band computing system 930, which may allow the computing systems to share components, distribute tasks, and/or perform other operations described herein (individually or as a single device).

Watch body computing system 960 can include one or more processors 979, a controller 977, a peripherals interface 961, a power system 995, and memory (e.g., a memory 980).

Power system 995 can include a charger input 996, a power-management integrated circuit (PMIC) 997, and a battery 998. In some embodiments, a watch body 820 and a wearable band 810 can have respective batteries (e.g., battery 998 and 959) and can share power with each other. Watch body 820 and wearable band 810 can receive a charge using a variety of techniques. In some embodiments, watch body 820 and wearable band 810 can use a wired charging assembly (e.g., power cords) to receive the charge. Alternatively, or in addition, watch body 820 and/or wearable band 810 can be configured for wireless charging. For example, a portable charging device can be designed to mate with a portion of watch body 820 and/or wearable band 810 and wirelessly deliver usable power to battery 998 of watch body 820 and/or battery 959 of wearable band 810. Watch body 820 and wearable band 810 can have independent power systems (e.g., power system 995 and 956, respectively) to enable each to operate independently. Watch body 820 and wearable band 810 can also share power (e.g., one can charge the other) via respective PMICs (e.g., PMICs 997 and 958) and charger inputs (e.g., 996 and 957) that can share power over power and ground conductors and/or over wireless charging antennas.

In some embodiments, peripherals interface 961 can include one or more sensors 921. Sensors 921 can include one or more coupling sensors 962 for detecting when watch body 820 is coupled with another electronic device (e.g., a wearable band 810). Sensors 921 can include one or more imaging sensors 963 (e.g., one or more of cameras 925, and/or separate imaging sensors 963 (e.g., thermal-imaging sensors)). In some embodiments, sensors 921 can include one or more SpO2 sensors 964. In some embodiments, sensors 921 can include one or more biopotential-signal sensors (e.g., EMG sensors 965, which may be disposed on an interior, user-facing portion of watch body 820 and/or wearable band 810). In some embodiments, sensors 921 may include one or more capacitive sensors 966. In some embodiments, sensors 921 may include one or more heart rate sensors 967. In some embodiments, sensors 921 may include one or more IMU sensors 968. In some embodiments, one or more IMU sensors 968 can be configured to detect movement of a user’s hand or other location where watch body 820 is placed or held.

In some embodiments, one or more of sensors 921 may provide an example human-machine interface. For example, a set of neuromuscular sensors, such as EMG sensors 965, may be arranged circumferentially around wearable band 810 with an interior surface of EMG sensors 965 being configured to contact a user’s skin. Any suitable number of neuromuscular sensors may be used (e.g., between 2 and 20 sensors). The number and arrangement of neuromuscular sensors may depend on the particular application for which the wearable device is used. For example, wearable band 810 can be used to generate control information for controlling an augmented reality system, a robot, controlling a vehicle, scrolling through text, controlling a virtual avatar, or any other suitable control task.

In some embodiments, neuromuscular sensors may be coupled together using flexible electronics incorporated into the wireless device, and the output of one or more of the sensing components can be optionally processed using hardware signal processing circuitry (e.g., to perform amplification, filtering, and/or rectification). In other embodiments, at least some signal processing of the output of the sensing components can be performed in software such as processors 979. Thus, signal processing of signals sampled by the sensors can be performed in hardware, software, or by any suitable combination of hardware and software, as aspects of the technology described herein are not limited in this respect.

Neuromuscular signals may be processed in a variety of ways. For example, the output of EMG sensors 965 may be provided to an analog front end, which may be configured to perform analog processing (e.g., amplification, noise reduction, filtering, etc.) on the recorded signals. The processed analog signals may then be provided to an analog-to-digital converter, which may convert the analog signals to digital signals that can be processed by one or more computer processors. Furthermore, although this example is as discussed in the context of interfaces with EMG sensors, the embodiments described herein can also be implemented in wearable interfaces with other types of sensors including, but not limited to, mechanomyography (MMG) sensors, sonomyography (SMG) sensors, and electrical impedance tomography (EIT) sensors.

In some embodiments, peripherals interface 961 includes a near-field communication (NFC) component 969, a global-position system (GPS) component 970, a long-term evolution (LTE) component 971, and/or a Wi-Fi and/or Bluetooth communication component 972. In some embodiments, peripherals interface 961 includes one or more buttons 973 (e.g., peripheral buttons 823 and 827 in FIG. 8), which, when selected by a user, cause operation to be performed at watch body 820. In some embodiments, the peripherals interface 961 includes one or more indicators, such as a light emitting diode (LED), to provide a user with visual indicators (e.g., message received, low battery, active microphone and/or camera, etc.).

Watch body 820 can include at least one display 805 for displaying visual representations of information or data to a user, including user-interface elements and/or three-dimensional virtual objects. The display can also include a touch screen for inputting user inputs, such as touch gestures, swipe gestures, and the like. Watch body 820 can include at least one speaker 974 and at least one microphone 975 for providing audio signals to the user and receiving audio input from the user. The user can provide user inputs through microphone 975 and can also receive audio output from speaker 974 as part of a haptic event provided by haptic controller 978. Watch body 820 can include at least one camera 925, including a front camera 925a and a rear camera 925b. Cameras 925 can include ultra-wide-angle cameras, wide angle cameras, fish-eye cameras, spherical cameras, telephoto cameras, depth-sensing cameras, or other types of cameras.

Watch body computing system 960 can include one or more haptic controllers 978 and associated componentry (e.g., haptic devices 976) for providing haptic events at watch body 820 (e.g., a vibrating sensation or audio output in response to an event at the watch body 820). Haptic controllers 978 can communicate with one or more haptic devices 976, such as electroacoustic devices, including a speaker of the one or more speakers 974 and/or other audio components and/or electromechanical devices that convert energy into linear motion such as a motor, solenoid, electroactive polymer, piezoelectric actuator, electrostatic actuator, or other tactile output generating components (e.g., a component that converts electrical signals into tactile outputs on the device). Haptic controller 978 can provide haptic events that are capable of being sensed by a user of watch body 820. In some embodiments, one or more haptic controllers 978 can receive input signals from an application of applications 982.

In some embodiments, wearable band computing system 930 and/or watch body computing system 960 can include memory 980, which can be controlled by one or more memory controllers of controllers 977. In some embodiments, software components stored in memory 980 include one or more applications 982 configured to perform operations at the watch body 820. In some embodiments, one or more applications 982 may include games, word processors, messaging applications, calling applications, web browsers, social media applications, media streaming applications, financial applications, calendars, clocks, etc. In some embodiments, software components stored in memory 980 include one or more communication interface modules 983 as defined above. In some embodiments, software components stored in memory 980 include one or more graphics modules 984 for rendering, encoding, and/or decoding audio and/or visual data and one or more data management modules 985 for collecting, organizing, and/or providing access to data 987 stored in memory 980. In some embodiments, one or more of applications 982 and/or one or more modules can work in conjunction with one another to perform various tasks at the watch body 820.

In some embodiments, software components stored in memory 980 can include one or more operating systems 981 (e.g., a Linux-based operating system, an Android operating system, etc.). Memory 980 can also include data 987. Data 987 can include profile data 988A, sensor data 989A, media content data 990, and application data 991.

It should be appreciated that watch body computing system 960 is an example of a computing system within watch body 820, and that watch body 820 can have more or fewer components than shown in watch body computing system 960, can combine two or more components, and/or can have a different configuration and/or arrangement of the components. The various components shown in watch body computing system 960 are implemented in hardware, software, firmware, or a combination thereof, including one or more signal processing and/or application-specific integrated circuits.

Turning to the wearable band computing system 930, one or more components that can be included in wearable band 810 are shown. Wearable band computing system 930 can include more or fewer components than shown in watch body computing system 960, can combine two or more components, and/or can have a different configuration and/or arrangement of some or all of the components. In some embodiments, all, or a substantial portion of the components of wearable band computing system 930 are included in a single integrated circuit. Alternatively, in some embodiments, components of wearable band computing system 930 are included in a plurality of integrated circuits that are communicatively coupled. As described above, in some embodiments, wearable band computing system 930 is configured to couple (e.g., via a wired or wireless connection) with watch body computing system 960, which allows the computing systems to share components, distribute tasks, and/or perform other operations described herein (individually or as a single device).

Wearable band computing system 930, similar to watch body computing system 960, can include one or more processors 949, one or more controllers 947 (including one or more haptics controllers 948), a peripherals interface 931 that can includes one or more sensors 913 and other peripheral devices, a power source (e.g., a power system 956), and memory (e.g., a memory 950) that includes an operating system (e.g., an operating system 951), data (e.g., data 954 including profile data 988B, sensor data 989B, etc.), and one or more modules (e.g., a communications interface module 952, a data management module 953, etc.).

One or more of sensors 913 can be analogous to sensors 921 of watch body computing system 960. For example, sensors 913 can include one or more coupling sensors 932, one or more SpO2 sensors 934, one or more EMG sensors 935, one or more capacitive sensors 936, one or more heart rate sensors 937, and one or more IMU sensors 938.

Peripherals interface 931 can also include other components analogous to those included in peripherals interface 961 of watch body computing system 960, including an NFC component 939, a GPS component 940, an LTE component 941, a Wi-Fi and/or Bluetooth communication component 942, and/or one or more haptic devices 946 as described above in reference to peripherals interface 961. In some embodiments, peripherals interface 931 includes one or more buttons 943, a display 933, a speaker 944, a microphone 945, and a camera 955. In some embodiments, peripherals interface 931 includes one or more indicators, such as an LED.

It should be appreciated that wearable band computing system 930 is an example of a computing system within wearable band 810, and that wearable band 810 can have more or fewer components than shown in wearable band computing system 930, combine two or more components, and/or have a different configuration and/or arrangement of the components. The various components shown in wearable band computing system 930 can be implemented in one or more of a combination of hardware, software, or firmware, including one or more signal processing and/or application-specific integrated circuits.

Wrist-wearable device 800 with respect to FIG. 8 is an example of wearable band 810 and watch body 820 coupled together, so wrist-wearable device 800 will be understood to include the components shown and described for wearable band computing system 930 and watch body computing system 960. In some embodiments, wrist-wearable device 800 has a split architecture (e.g., a split mechanical architecture, a split electrical architecture, etc.) between watch body 820 and wearable band 810. In other words, all of the components shown in wearable band computing system 930 and watch body computing system 960 can be housed or otherwise disposed in a combined wrist-wearable device 800 or within individual components of watch body 820, wearable band 810, and/or portions thereof (e.g., a coupling mechanism 816 of wearable band 810).

The techniques described above can be used with any device for sensing neuromuscular signals but could also be used with other types of wearable devices for sensing neuromuscular signals (such as body-wearable or head-wearable devices that might have neuromuscular sensors closer to the brain or spinal column).

In some embodiments, wrist-wearable device 800 can be used in conjunction with a head-wearable device (e.g., AR system 1000 and VR system 1110) and/or an HIPD, and wrist-wearable device 800 can also be configured to be used to allow a user to control any aspect of the artificial reality (e.g., by using EMG-based gestures to control user interface objects in the artificial reality and/or by allowing a user to interact with the touchscreen on the wrist-wearable device to also control aspects of the artificial reality). Having thus described example wrist-wearable devices, attention will now be turned to example head-wearable devices, such AR system 1000 and VR system 1110.

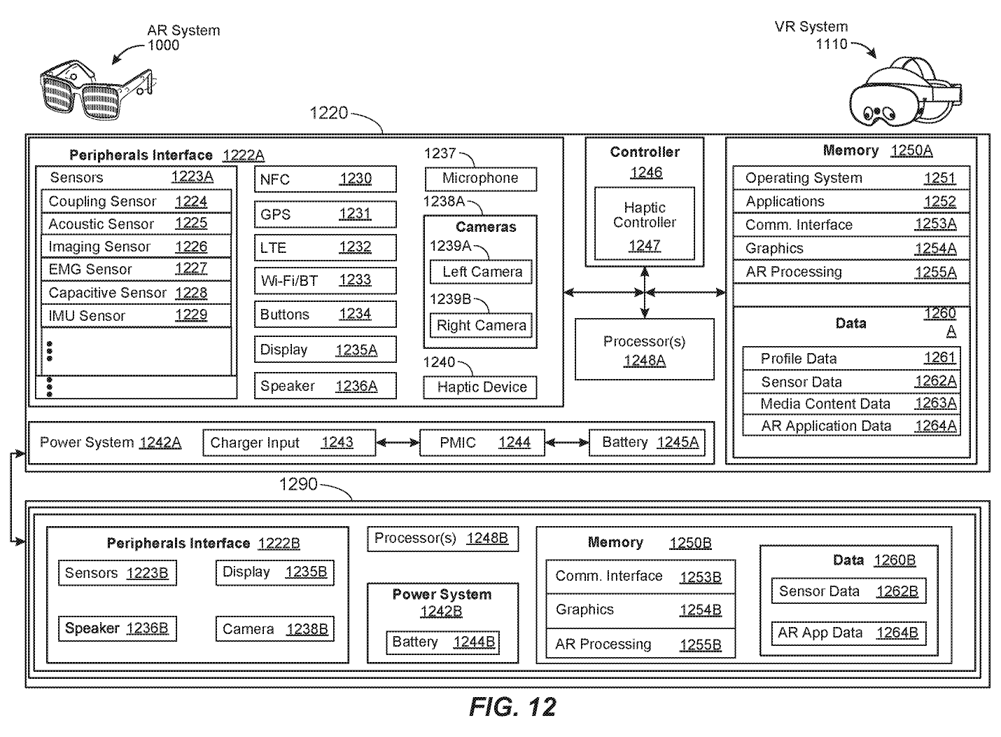

FIG. 10 is a schematic diagram illustrating an example of an AR system 1000, according to some embodiments of the subject disclosure. FIG. 10 shows an example visual depiction of the AR system 1000, including an eyewear device 1002 (which may also be described herein as augmented-reality glasses, and/or smart glasses). AR system 1000 can include additional electronic components that are not shown in FIG. 10, such as a wearable accessory device and/or an intermediary processing device, in electronic communication or otherwise configured to be used in conjunction with the eyewear device 1002. In some embodiments, the wearable accessory device and/or the intermediary processing device may be configured to couple with eyewear device 1002 via a coupling mechanism in electronic communication with a coupling sensor 1224 (FIG. 12), where coupling sensor 1224 can detect when an electronic device becomes physically or electronically coupled with eyewear device 1002. In some embodiments, eyewear device 1002 can be configured to couple to a housing 1290 (FIG. 12), which may include one or more additional coupling mechanisms configured to couple with additional accessory devices. The components shown in FIG. 10 can be implemented in hardware, software, firmware, or a combination thereof, including one or more signal-processing components and/or application-specific integrated circuits (ASICs).

Eyewear device 1002 includes mechanical glasses components, including a frame 1004 configured to hold one or more lenses (e.g., one or both lenses 1006-1 and 1006-2). One of ordinary skill in the art will appreciate that eyewear device 1002 can include additional mechanical components, such as hinges configured to allow portions of frame 1004 of eyewear device 1002 to be folded and unfolded, a bridge configured to span the gap between lenses 1006-1 and 1006-2 and rest on the user’s nose, nose pads configured to rest on the bridge of the nose and provide support for eyewear device 1002, earpieces configured to rest on the user’s ears and provide additional support for eyewear device 1002, temple arms configured to extend from the hinges to the earpieces of eyewear device 1002, and the like. One of ordinary skill in the art will further appreciate that some examples of AR system 1000 can include none of the mechanical components described herein. For example, smart contact lenses configured to present artificial reality to users may not include any components of eyewear device 1002.

Eyewear device 1002 includes electronic components, many of which will be described in more detail below with respect to FIG. 12. Some example electronic components are illustrated in FIG. 10, including acoustic sensors 1025-1, 1025-2, 1025-3, 1025-4, 1025-5, and 1025-6, which can be distributed along a substantial portion of the frame 1004 of eyewear device 1002. Eyewear device 1002 also includes a left camera 1039A and a right camera 1039B, which are located on different sides of the frame 1004. Eyewear device 1002 also includes a processor 1048 (or any other suitable type or form of integrated circuit) that is embedded into a portion of the frame 1004.

FIGS. 11A and 11B are schematic diagrams illustrating examples of VR systems 1100, according to some embodiments of the subject disclosure. VR system 1110 includes a head-mounted display (HMD) 1112 (e.g., also referred to herein as an AR headset, a head-wearable device, a VR headset, etc.), in accordance with some embodiments. As noted, some AR systems (e.g., AR system 1000) may, instead of blending an artificial reality with actual reality, substantially replace one or more of a user’s visual and/or other sensory perceptions of the real world with a virtual experience (e.g., AR systems 600 and 700).

HMD 1112 includes a front body 1114 and a frame 1116 (e.g., a strap or band) shaped to fit around a user’s head. In some embodiments, front body 1114 and/or frame 1116 include one or more electronic elements for facilitating presentation of and/or interactions with an AR and/or VR system (e.g., displays, IMUs, tracking emitters or detectors). In some embodiments, HMD 1112 includes output audio transducers (e.g., an audio transducer 1118), as shown in FIG. 11B. In some embodiments, one or more components, such as the output audio transducer(s) 1118 and frame 1116, can be configured to attach and detach (e.g., are detachably attachable) to HMD 1112 (e.g., a portion or all of frame 1116, and/or audio transducer 1118), as shown in FIG. 11B. In some embodiments, coupling a detachable component to HMD 1112 causes the detachable component to come into electronic communication with HMD 1112.

FIGS. 11A and 11B also show that VR system 1110 includes one or more cameras, such as left camera 1139A and right camera 1139B, which can be analogous to left and right cameras 1039A and 1039B on frame 1004 of eyewear device 1002. In some embodiments, VR system 1110 includes one or more additional cameras (e.g., cameras 1139C and 1139D), which can be configured to augment image data obtained by left and right cameras 1139A and 1139B by providing more information. For example, camera 1139C can be used to supply color information that is not discerned by cameras 1139A and 1139B. In some embodiments, one or more of cameras 1139A to 1139D can include an optional IR cut filter configured to remove IR light from being received at the respective camera sensors.

FIG. 12 is a block diagram illustrating an example of system components of artificial and VR systems. The system components include a computing system 1220 and an optional housing 1290, each of which show components that can be included in AR system 1000 and/or VR system 1110. In some embodiments, more or fewer components can be included in optional housing 1290 depending on practical restraints of the respective AR system being described.

In some embodiments, computing system 1220 can include one or more peripherals interfaces 1222A and/or optional housing 1290 can include one or more peripherals interfaces 1222B. Each of computing system 1220 and optional housing 1290 can also include one or more power systems 1242A and 1242B, one or more controllers 1246 (including one or more haptic controllers 1247), one or more processors 1248A and 1248B (as defined above, including any of the examples provided), and memory 1250A and 1250B, which can all be in electronic communication with each other. For example, the one or more processors 1248A and 1248B can be configured to execute instructions stored in memory 1250A and 1250B, which can cause a controller of one or more of controllers 1246 to cause operations to be performed at one or more peripheral devices connected to peripherals interface 1222A and/or 1222B. In some embodiments, each operation described can be powered by electrical power provided by power system 1242A and/or 1242B.

In some embodiments, peripherals interface 1222A can include one or more devices configured to be part of computing system 1220, some of which have been defined above and/or described with respect to the wrist-wearable devices shown in FIGS. 8 and 9. For example, peripherals interface 1222A can include one or more sensors 1223A. Some example sensors 1223A include one or more coupling sensors 1224, one or more acoustic sensors 1225, one or more imaging sensors 1226, one or more EMG sensors 1227, one or more capacitive sensors 1228, one or more IMU sensors 1229, and/or any other types of sensors explained above or described with respect to any other embodiments discussed herein.

In some embodiments, peripherals interfaces 1222A and 1222B can include one or more additional peripheral devices, including one or more NFC devices 1230, one or more GPS devices 1231, one or more LTE devices 1232, one or more Wi-Fi and/or Bluetooth devices 1233, one or more buttons 1234 (e.g., including buttons that are slidable or otherwise adjustable), one or more displays 1235A and 1235B, one or more speakers 1236A and 1236B, one or more microphones 1237, one or more cameras 1238A and 1238B (e.g., including the left camera 1239A and/or a right camera 1239B), one or more haptic devices 1240, and/or any other types of peripheral devices defined above or described with respect to any other embodiments discussed herein.

AR systems can include a variety of types of visual feedback mechanisms (e.g., presentation devices). For example, display devices in AR system 1000 and/or VR system 1110 can include one or more liquid-crystal displays (LCDs), light emitting diode (LED) displays, organic LED (OLED) displays, and/or any other suitable types of display screens. AR systems can include a single display screen (e.g., configured to be seen by both eyes), and/or can provide separate display screens for each eye, which can allow for additional flexibility for varifocal adjustments and/or for correcting a refractive error associated with a user’s vision. Some embodiments of AR systems also include optical subsystems having one or more lenses (e.g., conventional concave or convex lenses, Fresnel lenses, or adjustable liquid lenses) through which a user can view a display screen.

For example, respective displays 1235A and 1235B can be coupled to each of the lenses 1006-1 and 1006-2 of AR system 1000. Displays 1235A and 1235B may be coupled to each of lenses 1006-1 and 1006-2, which can act together or independently to present an image or series of images to a user. In some embodiments, AR system 1000 includes a single display 1235A or 1235B (e.g., a near-eye display) or more than two displays 1235A and 1235B. In some embodiments, a first set of one or more displays 1235A and 1235B can be used to present an augmented-reality environment, and a second set of one or more display devices 1235A and 1235B can be used to present a VR environment. In some embodiments, one or more waveguides are used in conjunction with presenting AR content to the user of AR system 1000 (e.g., as a means of delivering light from one or more displays 1235A and 1235B to the user’s eyes). In some embodiments, one or more waveguides are fully or partially integrated into the eyewear device 1002. Additionally, or alternatively to display screens, some AR systems include one or more projection systems. For example, display devices in AR system 1000 and/or VR system 1110 can include micro-LED projectors that project light (e.g., using a waveguide) into display devices, such as clear combiner lenses that allow ambient light to pass through. The display devices can refract the projected light toward a user’s pupil and can enable a user to simultaneously view both AR content and the real world. AR systems can also be configured with any other suitable type or form of image projection system. In some embodiments, one or more waveguides are provided additionally or alternatively to the one or more display(s) 1235A and 1235B.

Computing system 1220 and/or optional housing 1290 of AR system 1000 or VR system 1110 can include some or all of the components of a power system 1242A and 1242B. Power systems 1242A and 1242B can include one or more charger inputs 1243, one or more PMICs 1244, and/or one or more batteries 1245A and 1244B.

Memory 1250A and 1250B may include instructions and data, some or all of which may be stored as non-transitory computer-readable storage media within the memories 1250A and 1250B. For example, memory 1250A and 1250B can include one or more operating systems 1251, one or more applications 1252, one or more communication interface applications 1253A and 1253B, one or more graphics applications 1254A and 1254B, one or more AR processing applications 1255A and 1255B, and/or any other types of data defined above or described with respect to any other embodiments discussed herein.

Memory 1250A and 1250B also include data 1260A and 1260B, which can be used in conjunction with one or more of the applications discussed above. Data 1260A and 1260B can include profile data 1261, sensor data 1262A and 1262B, media content data 1263A, AR application data 1264A and 1264B, and/or any other types of data defined above or described with respect to any other embodiments discussed herein.

In some embodiments, controller 1246 of eyewear device 1002 may process information generated by sensors 1223A and/or 1223B on eyewear device 1002 and/or another electronic device within AR system 1000. For example, controller 1246 can process information from acoustic sensors 1025-1 and 1025-2. For each detected sound, controller 1246 can perform a direction of arrival (DOA) estimation to estimate a direction from which the detected sound arrived at eyewear device 1002 of AR system 1000. As one or more of acoustic sensors 1225 (e.g., the acoustic sensors 1025-1, 1025-2) detects sounds, controller 1246 can populate an audio data set with the information (e.g., represented in FIG. 12 as sensor data 1262A and 1262B).

In some embodiments, a physical electronic connector can convey information between eyewear device 1002 and another electronic device and/or between one or more processors 1048, 1248A, 1248B of AR system 1000 or VR system 1110 and controller 1246. The information can be in the form of optical data, electrical data, wireless data, or any other transmittable data form. Moving the processing of information generated by eyewear device 1002 to an intermediary processing device can reduce weight and heat in the eyewear device, making it more comfortable and safer for a user. In some embodiments, an optional wearable accessory device (e.g., an electronic neckband) is coupled to eyewear device 1002 via one or more connectors. The connectors can be wired or wireless connectors and can include electrical and/or non-electrical (e.g., structural) components. In some embodiments, eyewear device 1002 and the wearable accessory device can operate independently without any wired or wireless connection between them.

AR systems can include various types of computer vision components and subsystems. For example, AR system 1000 and/or VR system 1110 can include one or more optical sensors such as two-dimensional (2D) or three-dimensional (3D) cameras, time-of-flight depth sensors, structured light transmitters and detectors, single-beam or sweeping laser rangefinders, 3D LiDAR sensors, and/or any other suitable type or form of optical sensor. An AR system can process data from one or more of these sensors to identify a location of a user and/or aspects of the user’s real-world physical surroundings, including the locations of real-world objects within the real-world physical surroundings. In some embodiments, the methods described herein are used to map the real world, to provide a user with context about real-world surroundings, and/or to generate digital twins (e.g., interactable virtual objects), among a variety of other functions. For example, FIGS. 11A and 11B show VR system 1110 having cameras 1139A to 1139D, which can be used to provide depth information for creating a voxel field and a two-dimensional mesh to provide object information to the user to avoid collisions.

In some embodiments, AR system 1000 and/or VR system 1110 can include haptic (tactile) feedback systems, which may be incorporated into headwear, gloves, body suits, handheld controllers, environmental devices (e.g., chairs or floormats), and/or any other type of device or system, such as the wearable devices discussed herein. The haptic feedback systems may provide various types of cutaneous feedback, including vibration, force, traction, shear, texture, and/or temperature. The haptic feedback systems may also provide various types of kinesthetic feedback, such as motion and compliance. The haptic feedback may be implemented using motors, piezoelectric actuators, fluidic systems, and/or a variety of other types of feedback mechanisms. The haptic feedback systems may be implemented independently of other AR devices, within other AR devices, and/or in conjunction with other AR devices.

In some embodiments of an artificial reality system, such as AR system 1000 and/or VR system 1110, ambient light (e.g., a live feed of the surrounding environment that a user would normally see) can be passed through a display element of a respective head-wearable device presenting aspects of the AR system. In some embodiments, ambient light can be passed through a portion that is less than all of an AR environment presented within a user’s field of view (e.g., a portion of the AR environment co-located with a physical object in the user’s real-world environment that is within a designated boundary (e.g., a guardian boundary) configured to be used by the user while they are interacting with the AR environment). For example, a visual user interface element (e.g., a notification user interface element) can be presented at the head-wearable device, and an amount of ambient light (e.g., 15-50% of the ambient light) can be passed through the user interface element such that the user can distinguish at least a portion of the physical environment over which the user interface element is being displayed.

An aspect of the subject technology is directed to a device including at least one semiconductor package formed on a substrate, and a diamond heat spreader arranged over the at least one semiconductor package. The substrate and the diamond heat spreader are flexible.

In some implementations, the diamond heat spreader comprises a first polymer layer and a second polymer layer formed on opposing sides of a layer of diamond.

In one or more implementations, the first polymer layer and the second polymer layer each have a thickness within a range of about 30 µm to 60 µm, and wherein the layer of diamond has a thickness between 10 µm and 40 µm.

In some implementations, a grain size of the layer of diamond is within a range of about 2.5 µm to 3.5 µm.

In one or more implementations, the first polymer layer and the second polymer layer each comprise a thermoplastic polymer.

In some implementations, the first polymer layer and the second polymer layer each comprise polypropylene, polyimide and/or polyethylene terephthalate.

In one or more implementations, the diamond heat spreader comprises a diamond layer having a thickness within a range of about 20 µm and 50 µm.

In some implementations, the substrate comprises a polymer including polyimide or polyethylene terephthalate (PET).

Another aspect of the subject technology is directed to a method including forming a layer of diamond over a flexible substrate, treating a first surface of the layer of diamond using an oxygen plasma. The method further comprises forming a first encapsulating layer on the treated first surface of the layer of diamond.

In some implementations, the layer of diamond has a thickness between 20 µm and 50 µm and wherein the first encapsulating layer comprises a first polymer layer and has a thickness between 30 µm and 60 µm.

In one or more implementations, the method further comprises removing the flexible substrate to expose a second surface of the layer of diamond over.

In some implementations, the method further comprises forming a second polymer layer on the exposed second surface of the layer of diamond, wherein the second polymer layer has a thickness between 30 µm and 60 µm.

In one or more implementations, the first polymer layer and the second polymer layer comprise a thermoplastic polymer.

In some implementations, the first polymer layer and the second polymer layer each comprise polypropylene, polyimide and/or polyethylene terephthalate.

In one or more implementations, a grain size of the layer of diamond is within a range of about 2.5 µm to 3.5 µm.

In some implementations, the flexible substrate comprises a polymer including polyimide or polyethylene terephthalate (PET).

Yet another aspect of the subject technology is directed to a wearable device including at least one semiconductor package including electronic circuitry formed on a substrate, and a diamond heat spreader arranged over the at least one semiconductor package. The substrate and the diamond heat spreader are flexible.

In one or more implementations, the wearable device comprises an augmented reality (AR) device, a virtual reality (VR) device, smart glasses or a wristband.

In some implementations, the diamond heat spreader comprises a first polymer layer and a second polymer layer formed on opposing sides of a layer of diamond.

In one or more implementations, the first polymer layer and the second polymer layer each have a thickness within a range of about 30 µm to 60 µm, the layer of diamond has a thickness between 10 µm and 40 µm, and a grain size of the layer of diamond is within a range of about 2.5 µm to 3.5 µm.

In some implementations, the word “exemplary” is used herein to mean “serving as an example, instance, or illustration.” Any embodiment described herein as “exemplary” is not necessarily to be construed as preferred or advantageous over other embodiments. Phrases such as an aspect, the aspect, another aspect, some aspects, one or more aspects, an implementation, the implementation, another implementation, some implementations, one or more implementations, an embodiment, the embodiment, another embodiment, some embodiments, one or more embodiments, a configuration, the configuration, another configuration, some configurations, one or more configurations, the subject technology, the disclosure, the present disclosure, other variations thereof and alike are for convenience and do not imply that a disclosure relating to such phrase(s) is essential to the subject technology or that such disclosure applies to all configurations of the subject technology. A disclosure relating to such phrase(s) may apply to all configurations, or one or more configurations. A disclosure relating to such phrase(s) may provide one or more examples. A phrase such as an aspect or some aspects may refer to one or more aspects and vice versa, and this applies similarly to other foregoing phrases.

A reference to an element in the singular is not intended to mean “one and only one” unless specifically stated, but rather “one or more.” Pronouns in the masculine (e.g., his) include the feminine and neuter gender (e.g., her and its) and vice versa. The term “some” refers to one or more. Underlined and/or italicized headings and subheadings are used for convenience only, do not limit the subject technology, and are not referred to in connection with the interpretation of the description of the subject technology. Relational terms such as first and second and the like may be used to distinguish one entity or action from another without necessarily requiring or implying any actual such relationship or order between such entities or actions. All structural and functional equivalents to the elements of the various configurations described throughout this disclosure that are known or later come to be known to those of ordinary skill in the art are expressly incorporated herein by reference and intended to be encompassed by the subject technology. Moreover, nothing disclosed herein is intended to be dedicated to the public, regardless of whether such disclosure is explicitly recited in the above description. No clause element is to be construed under the provisions of 35 U.S.C. §112, sixth paragraph, unless the element is expressly recited using the phrase “means for” or, in the case of a method clause, the element is recited using the phrase “step for.”

While this specification contains many specifics, these should not be construed as limitations on the scope of what may be described, but rather as descriptions of particular implementations of the subject matter. Certain features that are described in this specification in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially described as such, one or more features from a described combination can in some cases be excised from the combination, and the described combination may be directed to a sub-combination or variation of a sub-combination.

The subject matter of this specification has been described in terms of particular aspects, but other aspects can be implemented and are within the scope of the following clauses. For example, while operations are depicted in the drawings in a particular order, this should not be understood as requiring that such operations be performed in the particular order shown or in sequential order, or that all illustrated operations be performed, to achieve desirable results. The actions recited in the clauses can be performed in a different order and still achieve desirable results. As one example, the processes depicted in the accompanying figures do not necessarily require the particular order shown, or sequential order, to achieve desirable results. In certain circumstances, multitasking and parallel processing may be advantageous. Moreover, the separation of various system components in the aspects described above should not be understood as requiring such separation in all aspects, and it should be understood that the described program components and systems can generally be integrated together in a single software product or packaged into multiple software products.

The title, background, brief description of the drawings, abstract, and drawings are hereby incorporated into the disclosure and are provided as illustrative examples of the disclosure, not as restrictive descriptions. It is submitted with the understanding that they will not be used to limit the scope or meaning of the clauses. In addition, in the detailed description, it can be seen that the description provides illustrative examples, and the various features are grouped together in various implementations for the purpose of streamlining the disclosure. The method of disclosure is not to be interpreted as reflecting an intention that the described subject matter requires more features than are expressly recited in each clause. Rather, as the clauses reflect, inventive subject matter lies in less than all features of a single disclosed configuration or operation. The clauses are hereby incorporated into the detailed description, with each clause standing on its own as a separately described subject matter.

As used herein, the phrase “at least one of” preceding a series of items, with the terms “and” or “or” to separate any of the items, modifies the list as a whole, rather than each member of the list (i.e., each item).

To the extent that the term “include,” “have,” or the like is used in the description or the claims, such term is intended to be inclusive in a manner similar to the term “comprise” as “comprise” is interpreted when employed as a transitional word in a claim.

A reference to an element in the singular is not intended to mean “one and only one” unless specifically stated, but rather “one or more.” All structural and functional equivalents to the elements of the various configurations described throughout this disclosure that are known or later come to be known to those of ordinary skill in the art are expressly incorporated herein by reference and intended to be encompassed by the subject technology. Moreover, nothing disclosed herein is intended to be dedicated to the public regardless of whether such disclosure is explicitly recited in the above description.

While this specification contains many specifics, these should not be construed as limitations on the scope of what may be claimed, but rather as descriptions of particular implementations of the subject matter. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

What is claimed is:

1. A device comprising:
at least one semiconductor package formed on a substrate; and
a diamond heat spreader arranged over the at least one semiconductor package,
wherein the substrate and the diamond heat spreader are flexible.

2. The device of claim 1, wherein the diamond heat spreader comprises a first polymer layer and a second polymer layer formed on opposing sides of a layer of diamond.

3. The device of claim 2, wherein the first polymer layer and the second polymer layer each have a thickness within a range of about 30 µm to 60 µm, and wherein the layer of diamond has a thickness between 10 µm and 40 µm.

4. The device of claim 2, wherein a grain size of the layer of diamond is within a range of about 2.5 µm to 3.5 µm.

5. The device of claim 2, wherein the first polymer layer and the second polymer layer each comprise a thermoplastic polymer.

6. The device of claim 2, wherein the first polymer layer and the second polymer layer each comprise polypropylene, polyimide and/or polyethylene terephthalate.

7. The device of claim 1, wherein the diamond heat spreader comprises a diamond layer having a thickness within a range of about 20 µm and 50 µm.

8. The device of claim 1, wherein the substrate comprises a polymer including polyimide or polyethylene terephthalate (PET).

9. A method comprising:
forming a layer of diamond over a flexible substrate;
treating a first surface of the layer of diamond using an oxygen plasma; and
forming a first encapsulating layer on the treated first surface of the layer of diamond.

10. The method of claim 9, wherein the layer of diamond has a thickness between 20 µm and 50 µm and wherein the first encapsulating layer comprises a first polymer layer and has a thickness between 30 µm and 60 µm.

11. The method of claim 10, further comprising removing the flexible substrate to expose a second surface of the layer of diamond over.

12. The method of claim 11, further comprising forming a second polymer layer on the exposed second surface of the layer of diamond, wherein the second polymer layer has a thickness between 30 µm and 60 µm.

13. The method of claim 12, wherein the first polymer layer and the second polymer layer comprise a thermoplastic polymer.

14. The method of claim 12, wherein the first polymer layer and the second polymer layer each comprise polypropylene, polyimide and/or polyethylene terephthalate.

15. The method of claim 9, wherein a grain size of the layer of diamond is within a range of about 2.5 µm to 3.5 µm.

16. The method of claim 9, wherein the flexible substrate comprises a polymer including polyimide or polyethylene terephthalate (PET).

17. A wearable device comprising:
at least one semiconductor package including electronic circuitry formed on a substrate; and
a diamond heat spreader arranged over the at least one semiconductor package,
wherein the substrate and the diamond heat spreader are flexible.

18. The wearable device of claim 17, wherein the wearable device comprises an augmented reality (AR) device, a virtual reality (VR) device, smart glasses or a wristband.

19. The wearable device of claim 17, wherein the diamond heat spreader comprises a first polymer layer and a second polymer layer formed on opposing sides of a layer of diamond.

20. The wearable device of claim 19, wherein:
the first polymer layer and the second polymer layer each have a thickness within a range of about 30 µm to 60 µm,
the layer of diamond has a thickness between 10 µm and 40 µm, and
a grain size of the layer of diamond is within a range of about 2.5 µm to 3.5 µm.
